(19) United States
(12) Patent Application Publication
(10) Pub. No.: US 2026/0162743 A1
(43) Pub. Date: Jun. 11, 2026

(54) SOFT REPAIR CONTROL CIRCUIT, MEMORY, AND METHOD FOR REPAIRING MEMORY

(71) Applicant: CXMT Corporation, Hefei City (CN)

(72) Inventor: Wei ZHANG, Hefei City (CN)

(73) Assignee: CXMT Corporation, Hefei City (CN)

(21) Appl. No.: 19/260,409

(22) Filed: Jul. 4, 2025

Related U.S. Application Data
(63) Continuation of application No. PCT/CN2025/094296, filed on May 12, 2025.

(30) Foreign Application Priority Data
Dec. 9, 2024 (CN) 202411815017.2

(51) Int. Cl. G11C 29/02

(52) U.S. Cl. CPC G11C 29/023

(57) ABSTRACT

A soft repair control circuit includes a lock control circuit, an undo control circuit, a soft repair address latch circuit, and a soft repair address matching circuit. The lock control circuit locks an output latch control signal into a first level when a lock enable signal is at an active level. The undo control circuit maintains an output unchanged and the soft repair address latch circuit maintains an output unchanged when the latch control signal is locked into the first level and generates an undo flag signal at an active level according to an undo enable signal at an active level when the latch control signal is an inverted delayed signal of a soft repair pulse signal. The soft repair address matching circuit locks an output soft repair matching signal into an inactive level when the undo flag signal is at an active level.

### CROSS-REFERENCE TO RELATED APPLICATIONS

This is a continuation application of International Application No. PCT/CN 2025/094296 filed on May 12, 2025, which claims priority to Chinese Patent Application No. 202411815017.2 filed on Dec. 9, 2024. The disclosures of the above-referenced applications are hereby incorporated by reference in their entirety.

### BACKGROUND

With the continuous development of semiconductor technologies, the integration level of memory devices has been increasing, resulting in a sharp increase in the number of memory cells within a single memory chip. However, the increase in the number of memory cells has also led to the problem of memory defects. To improve the yield of memory and reduce production costs, redundant memory cells and post package repair technologies have been introduced. Specifically, the conventional hard post package repair (hard post package repair, HPPR) technology relies on non-volatile storage circuits (e.g., fuse arrays) to store addresses of defective cells, which are read and replaced upon startup to ensure a high yield.

In contrast, the soft post package repair (soft post package repair, SPPR) technology offers a more flexible and efficient repair solution. It enables direct writing of address information into volatile latch circuits via commands, streamlining the process and improving repair efficiency in a field use process. However, in a semiconductor memory supporting soft post package repair, how to further simplify the control circuit to achieve compatible execution of a plurality of soft repair commands transmitted by the memory controller has become a key problem that urgently needs to be solved.

### SUMMARY

The present disclosure relates to the technical field of semiconductors, and in particular to a soft repair control circuit, a memory, and a method for repairing a memory.

Embodiments of the present disclosure provide a soft repair control circuit, a memory, and a method for repairing a memory.

In a first aspect, a soft repair control circuit is provided according to the embodiments of the present disclosure. The soft repair control circuit includes: a lock control circuit, an undo control circuit, a soft repair address latch circuit, and a soft repair address matching circuit. The lock control circuit is configured to receive a lock enable signal, a soft repair activation signal, and a soft repair pulse signal, lock an output latch control signal into a first level when the lock enable signal is at an active level, and output an inverted delayed signal of the soft repair pulse signal as the latch control signal in response to the soft repair activation signal at an active level when the lock enable signal is at an inactive level; when the lock enable signal is at an active level, it is indicated that a soft repair lock operation is executed. The undo control circuit is configured to receive an undo enable signal and the latch control signal, maintain an output unchanged when the latch control signal is locked into the first level, and generate and output an undo flag signal at an active level according to the undo enable signalat an active level in response to a pulse on the latch control signal when the latch control signal is the inverted delayed signal of the soft repair pulse signal; when the undo enable signal is at an active level, it is indicated that a soft repair undo operation is executed. The soft repair address latch circuit is configured to receive a soft repair fail address and the latch control signal, maintain an output unchanged when the latch control signal is locked into the first level, and latch the soft repair fail address and output the soft repair fail address as a latched address in response to a pulse on the latch control signal when the latch control signal is the inverted delayed signal of the soft repair pulse signal. The soft repair address matching circuit is configured to receive the latched address and the undo flag signal, lock an output soft repair matching signal into an inactive level when the undo flag signal is at an active level, and match a target address with the latched address to generate and output the soft repair matching signal when the undo flag signal is at an inactive level; when the soft repair matching signal is at an active level, it is indicated that the target address successfully matches the latched address, and when the soft repair matching signal is at an inactive level, it is indicated that the target address does not successfully match the latched address. The target address is an address corresponding to an access operation in a normal operating mode.

In some embodiments, the lock control circuit includes: a lock-flag signal generation circuit and a latch control signal generation circuit. The lock-flag signal generation circuit is configured to receive the lock enable signal, the soft repair activation signal, and the soft repair pulse signal, generate and output the latch control signal at an active level in response to a pulse on the soft repair pulse signal when the lock enable signal is at an active level and the soft repair activation signal is at an active level, and generate and output a lock-flag signal at an inactive level when the lock enable signal is at an inactive level. The latch control signal generation circuit is configured to receive the lock-flag signal, the soft repair activation signal, and the soft repair pulse signal, lock the output latch control signal into the first level when the lock-flag signal is at an active level, and output the inverted delayed signal of the soft repair pulse signal as the latch control signal when the lock-flag signal is at an inactive level and the soft repair activation signal is at an active level.

In some embodiments, the lock-flag signal generation circuit includes: a first NAND gate and a D flip-flop. Input terminals of the first NAND gate separately receive the lock enable signal, the soft repair activation signal, and the soft repair pulse signal; an input terminal of the D flip-flop is electrically connected to a power supply terminal, a clock terminal of the D flip-flop is electrically connected to an output terminal of the first NAND gate, and an output terminal of the D flip-flop is configured to output the lock-flag signal. The latch control signal generation circuit includes: a delay unit, a second NAND gate, and an OR gate. An input terminal of the delay unit receives the soft repair pulse signal; a first input terminal of the second NAND gate receives the soft repair activation signal, and a second input terminal of the second NAND gate is electrically connected to an output terminal of the delay unit; a first input terminal of the OR gate is electrically connected to the output terminal of the D flip-flop, a second input terminal of the OR gate is electrically connected to an output terminal of the second NAND gate, and an output terminal of the OR gate is configured to output the latch control signal.

In some embodiments, the undo control circuit includes: a first latch and a NOT gate. An input terminal of the first latch receives the undo enable signal, and a control terminal of the first latch receives the latch control signal; an input terminal of the NOT gate is electrically connected to an output terminal of the first latch, and an output terminal of the NOT gate is configured to output the undo flag signal.

In some embodiments, the soft repair address latch circuit includes at least one sub-latch circuit, and one sub-latch circuit is selected as a target sub-latch circuit according to a preset order. The target sub-latch circuit is configured to receive the latch control signal and the soft repair fail address, maintain the currently output latched address unchanged when the latch control signal is locked into the first level, and latch the soft repair fail address into the latched address in response to a pulse on the latch control signal when the latch control signal is the inverted delayed signal of the soft repair pulse signal.

In some embodiments, the soft repair address matching circuit includes at least one sub-matching circuit. The at least one sub-matching circuit is connected to the at least one sub-latch circuit in a one-to-one correspondence manner, and one sub-matching circuit correspondingly connected to the target sub-latch circuit serves as a target sub-matching circuit. The target sub-matching circuit is configured to receive the undo flag signal and the target address, lock the output soft repair matching signal into an inactive level when the undo flag signal is at an active level, and match a corresponding latched address with the target address to generate and output a corresponding soft repair matching signal when the undo flag signal is at an inactive level.

In some embodiments, the target sub-latch circuit includes a plurality of second latches. The plurality of second latches are in one-to-one correspondence with a plurality of first address signals in the soft repair fail address and a plurality of second address signals in the latched address; an input terminal of each of the plurality of second latches receives a corresponding one of the plurality of first address signals, a control terminal of the second latch receives the latch control signal, and an output terminal of the second latch is configured to output a corresponding one of the plurality of second address signals.

In some embodiments, the target sub-matching circuit includes a plurality of exclusive NOR gates and an AND gate. The plurality of exclusive NOR gates are in one-to-one correspondence with the plurality of second latches and a plurality of third address signals in the target address; a first input terminal of each of the plurality of exclusive NOR gates receives a corresponding one of the plurality of third address signals, and a second input terminal of the exclusive NOR gate is electrically connected to the output terminal of a corresponding one of the plurality of second latches. One input terminal of the AND gate receives the undo flag signal, other input terminals of the AND gate are electrically connected to output terminals of the plurality of exclusive NOR gates in a one-to-one correspondence manner, and an output terminal of the AND gate is configured to output the soft repair matching signal.

In some embodiments, the lock control circuit is further configured to reset the latch control signal in response to a reset signal. The undo control circuit is further configured to reset the undo flag signal to an inactive level in response to the reset signal. The soft repair address latch circuit is further configured to reset the latched address in response to the reset signal.

In a second aspect, a memory is further provided according to the embodiments of the present disclosure. The memory includes a command decoding circuit and the soft repair control circuit according to the first aspect. The command decoding circuit is configured to receive a soft repair command, and generate an undo enable signalat an active level when a soft repair mode parameter in the soft repair command is a second preset value; and generate a lock enable signal at an active level when the soft repair mode parameter in the soft repair command is a third preset value. The soft repair control circuit is further configured to receive the undo enable signaland the lock enable signal, and control to execute a soft repair undo operation when the undo enable signal is at an active level; and control to execute a soft repair lock operation when the lock enable signal is at an active level.

In some embodiments, the command decoding circuit is further configured to generate a soft repair enable signal at an active level when the soft repair mode parameter in the soft repair command is a first preset value; when the soft repair enable signal is at an active level, it is indicated that the memory enters a soft repair mode. The command decoding circuit is further configured to, after the memory enters the soft repair mode, sequentially receive an activation command and a write command, decode the activation command to generate and output a soft repair activation signal and a soft repair fail address, and decode the write command to generate and output a soft repair pulse signal; when address information in the activation command indicates a bank corresponding to the soft repair control circuit, the soft repair activation signal at an active level is generated and transmitted to the soft repair control circuit. The soft repair control circuit is electrically connected to the command decoding circuit, and is configured to receive the soft repair activation signal, the soft repair fail address, and the soft repair pulse signal, and latch the soft repair fail address into a latched address according to the soft repair pulse signal when the soft repair activation signal is at an active level.

In some embodiments, the memory further includes: a row address decoding circuit and a bank. The command decoding circuit is further configured to generate the soft repair enable signal at an inactive level to indicate that the memory enters a normal operating mode when the soft repair mode parameter in the soft repair command is a fourth preset value. The command decoding circuit is further configured to receive the activation command and decode the activation command to generate and output the target address when the memory is in the normal operating mode. The soft repair control circuit is further configured to match the target address with the latched address when the memory is in the normal operating mode, and generate and output a soft repair matching signal at an active level when the target address successfully matches the latched address. The row address decoding circuit is electrically connected to the soft repair control circuit, and is configured to receive the soft repair matching signal and the target address, and control to activate a word line of a corresponding soft repair redundant row in the bank according to the soft repair matching signal at an active level when the soft repair matching signal is at an active level.

In some embodiments, the command decoding circuit includes: a soft repair command decoder, a mode register, a soft repair signal generation circuit, an activation command decoder, and a write command decoder. The soft repair command decoder is configured to receive the soft repair command and write the soft repair mode parameter in the soft repair command into the mode register. The soft repair signal generation circuit is configured to receive the soft repair mode parameter stored in the mode register, and generate the soft repair enable signal at an active level when the soft repair mode parameter is the first preset value; generate the undo enable signal at an active level when the soft repair mode parameter is the second preset value; and generate the lock enable signal at an active level when the soft repair mode parameter is the third preset value. The activation command decoder is configured to receive the soft repair enable signal and the activation command, and decode the activation command to generate and output the soft repair activation signal and the soft repair fail address when the soft repair enable signal at an active level indicates that the memory enters the soft repair mode. The write command decoder is configured to receive the soft repair enable signal and the write command, and decode the write command to generate and output the soft repair pulse signal when the soft repair enable signal at an active level indicates that the memory enters the soft repair mode.

In some embodiments, the memory further includes: a fuse address matching circuit. The fuse address matching circuit is configured to receive a plurality of standard failed addresses from a fuse array, match the received target address with the plurality of standard failed addresses separately, and generate a plurality of standard matching signals according to matching results. The row address decoding circuit is further configured to receive the plurality of standard matching signals, and control to activate a word line of a corresponding standard redundant row in the bank according to the standard matching signal at an active level when any one of the plurality of standard matching signals is at an active level.

In some embodiments, the row address decoding circuit is further configured to control to activate a word line of a corresponding memory row in the bank according to the target address when both the soft repair matching signal and the standard matching signal are at an inactive level.

In a third aspect, a method for repairing a memory is provided according to the embodiments of the present disclosure. The method includes: receiving a soft repair command and decoding the soft repair command; determining a value of a soft repair mode parameter in the soft repair command; generating an undo enable signalat an active level to indicate execution of a soft repair undo operation when the soft repair mode parameter is a second preset value; locking a soft repair matching signal into an inactive level in response to the undo enable signalat an active level; generating a lock enable signal at an active level to indicate execution of a soft repair lock operation when the soft repair mode parameter is a third preset value; and maintaining a currently latched soft repair fail address unchanged and shielding the undo enable signal in response to the lock enable signal at an active level. When the soft repair matching signal is at an inactive level, it is indicated that a target address does not successfully match the latched soft repair fail address. The target address is an address corresponding to an access operation in a normal operating mode.

In some embodiments, the repair method further includes: generating a soft repair enable signal at an active level to indicate entry into a soft repair mode when the soft repair mode parameter in the soft repair command is a first preset value; receiving an activation command and a write command sequentially after the memory enters the soft repair mode; decoding the activation command to generate a soft repair activation signal and a soft repair fail address; decoding the write command to generate a soft repair pulse signal; and latching the soft repair fail address into a latched address according to the soft repair pulse signal in response to the soft repair activation signal at an active level.

In some embodiments, the repair method further includes: generating the soft repair enable signal at an inactive level to indicate that the memory enters the normal operating mode when the soft repair mode parameter in the soft repair command is a fourth preset value; receiving the activation command when the memory is in the normal operating mode; decoding the activation command to generate the target address; matching the target address with the latched soft repair fail address and generating the soft repair matching signal at an active level when the matching is successful; and controlling to activate a word line of a corresponding soft repair redundant row in a bank according to the soft repair matching signal at an active level.

### BRIEF DESCRIPTION OF DRAWINGS

FIG. 1 is a schematic diagram of a composition structure of a soft repair control circuit according to embodiments of the present disclosure;

FIG. 2 is a schematic diagram of a composition structure of a lock control circuit according to the embodiments of the present disclosure;

FIG. 3 is a schematic diagram of a composition structure of a lock-flag signal generation circuit and a latch control signal generation circuit according to the embodiments of the present disclosure;

FIG. 4 is a schematic diagram of a composition structure of an undo control circuit according to the embodiments of the present disclosure;

FIG. 5A is a schematic diagram of a composition structure of a soft repair address latch circuit and a soft repair address matching circuit according to the embodiments of the present disclosure;

FIG. 5B is a schematic diagram of another composition structure of a soft repair address latch circuit and a soft repair address matching circuit according to the embodiments of the present disclosure;

FIG. 6 is a schematic diagram of a composition structure of a target sub-latch circuit and a target sub-matching circuit according to the embodiments of the present disclosure;

FIG. 7 is a first schematic diagram of a composition structure of a memory according to the embodiments of the present disclosure;

FIG. 8 is a schematic diagram of a composition structure of a command decoding circuit according to the embodiments of the present disclosure;

FIG. 9 is a second schematic diagram of a composition structure of a memory according to the embodiments of the present disclosure;

FIG. 10 is a first signal timing diagram corresponding to a memory according to the embodiments of the present disclosure;

FIG. 11 is a second signal timing diagram corresponding to a memory according to the embodiments of the present disclosure; and

FIG. 12 is a flow chart of a method for repairing a memory according to the embodiments of the present disclosure.

### DETAILED DESCRIPTION

The technical solutions in embodiments of the present disclosure will be clearly and completely described below with reference to the drawings in the embodiments of the present disclosure. It can be understood that the specific embodiments described herein are merely illustrative of the related disclosures and are not intended to limit the present disclosure. In addition, it should be noted that for the convenience of description, only the portions relevant to the related disclosure are shown in the drawings.

Unless otherwise defined, all technical and scientific terms used herein have the same meaning as commonly understood by those skilled in the art to which the present disclosure pertains. The terms used herein are for the purpose of describing the embodiments of the present disclosure only and are not intended to limit the present disclosure.

In the following description, reference is made to “some embodiments” which describe subsets of all possible embodiments, but it can be understood that “some embodiments” may be the same subset or different subsets of all possible embodiments, and may be combined with each other without conflict.

It should be noted that the terms “first\second\third” referred to in the embodiments of the present disclosure are merely used for distinguishing similar objects and do not represent a specific ordering for the objects. It is understandable that “first\second\third” may be subjected to interchange of a specific order or sequence if permitted, such that the embodiments of the present disclosure described herein can be implemented in an order other than that shown or described herein.

To achieve compatible execution of various types of soft repair commands transmitted by the memory controller and improve the yield of the memory chip, a soft repair control circuit is provided according to the embodiments of the present disclosure. The soft repair control circuit includes: a lock control circuit, an undo control circuit, a soft repair address latch circuit, and a soft repair address matching circuit. The lock control circuit is configured to receive a lock enable signal, a soft repair activation signal, and a soft repair pulse signal, lock an output latch control signal into a first level when the lock enable signal at an active level indicates the execution of a soft repair lock operation, and output the soft repair pulse signal as the latch control signal in response to the soft repair activation signal at an active level when the lock enable signal is at an inactive level. The undo control circuit is configured to receive an undo enable signaland the latch control signal, maintain an output unchanged when the latch control signal is locked into the first level, and generate and output an undo flag signal at an active level according to the undo enable signalat an active level indicating the execution of a soft repair undo operation in response to a pulse on the latch control signal when the latch control signal is an inverted delayed signal of the soft repair pulse signal. The soft repair address latch circuit is configured to receive a soft repair fail address and the latch control signal, maintain an output unchanged when the latch control signal is locked into the first level, and latch the soft repair fail address and output the soft repair fail address as a latched address in response to a pulse on the latch control signal when the latch control signal is the inverted delayed signal of the soft repair pulse signal. The soft repair address matching circuit is configured to receive the latched address and the undo flag signal, lock an output soft repair matching signal into an inactive level when the undo flag signal is at an active level, and match a target address with the latched address to generate and output the soft repair matching signal when the undo flag signal is at an inactive level; when the soft repair matching signal is at an active level, it is indicated that the target address successfully matches the latched address, and when the soft repair matching signal is at an inactive level, it is indicated that the target address does not successfully match the latched address.

As such, when the lock enable signal at an active level indicates the execution of the soft repair lock operation, the lock control circuit may shield the soft repair pulse signal and output the lock control signal which is constant at the first level, so as to control the soft repair address latch circuit to remain in the locked state and no longer latch a new soft repair fail address, and instead maintain the currently latched soft repair fail address unchanged. In addition, the lock control signal at the first level may also shield a subsequently input soft repair undo enable signal indicating the execution of the soft repair undo operation, thereby executing the soft repair lock operation. At the same time, when the undo enable signal at an active level indicates the execution of the soft repair undo operation, the undo control circuit may output the undo flag signal locked at an active level, so as to control the soft repair matching signal output by the soft repair address matching circuit and locked at an inactive level to indicate that the matching is unsuccessful. As a result, the matching result of the previously latched latched address is shielded, and the soft repair operation is not executed accordingly, i.e., the previous soft repair operation is undone, thereby executing the soft repair undo operation. In this way, by using the newly added lock control circuit and undo control circuit, as well as the lock control signal output by the newly added lock control circuit and the undo flag signal output by the newly added undo control circuit, the soft repair control circuit can complete a plurality of operations such as soft repair fail address latching, soft repair locking, and soft repair undo based on the original soft repair address latch circuit and soft repair address matching circuit. On the premise of implementing various functions of soft repair specified in the standard, the circuit design is simplified, thereby saving the circuit area.

The embodiments of the present disclosure are described in detail below with reference to the drawings.

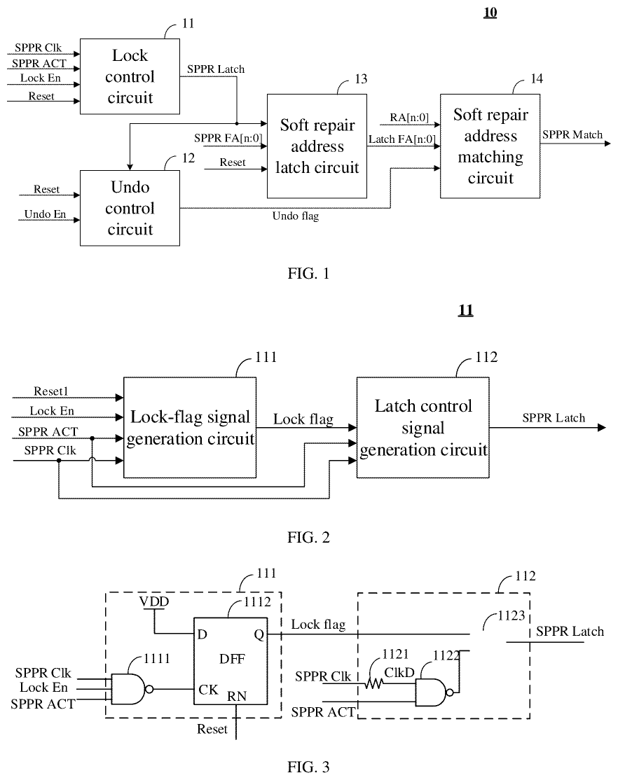

In an embodiment of the present disclosure, referring to FIG. 1, a schematic diagram of a composition structure of a soft repair control circuit 10 according to the embodiments of the present disclosure is illustrated. As shown in FIG. 1, the internal soft repair control circuit 10 includes: a lock control circuit 11, an undo control circuit 12, a soft repair address latch circuit 13, and a soft repair address matching circuit 14. The lock control circuit 11 is configured to receive a lock enable signal Lock En, a soft repair activation signal SPPR ACT, and a soft repair pulse signal SPPR Clk, lock an output latch control signal SPPR Latch into a first level when the lock enable signal Lock En is at an active level, and output the soft repair pulse signal SPPR Clk as the latch control signal SPPR Latch in response to the soft repair activation signal SPPR ACT at an active level when the lock enable signal Lock En is at an inactive level; when the lock enable signal Lock En is at an active level, it is indicated that a soft repair lock operation is executed. The undo control circuit 12 is configured to receive an undo enable signal Undo En and the latch control signal SPPR Latch, maintain an output unchanged when the latch control signal SPPR Latch is locked into the first level, and generate and output an undo flag signal Undo flag at an active level according to the undo enable signal Undo En at an active level in response to a pulse on the latch control signal SPPR Latch when the latch control signal SPPR Latch is an inverted delayed signal of the soft repair pulse signal SPPR Clk; when the undo enable signal Undo En is at an active level, it is indicated that a soft repair undo operation is executed. The soft repair address latch circuit 13 is configured to receive a soft repair fail address SPPR FA[n:0] and the latch control signal SPPR Latch, maintain an output unchanged when the latch control signal SPPR Latch is locked into the first level, and latch the soft repair fail address SPPR FA[n:0] and output the soft repair fail address as a latched address Latch FA[n:0] in response to a pulse on the latch control signal SPPR Latch when the latch control signal SPPR Latch is the inverted delayed signal of the soft repair pulse signal SPPR Clk. The soft repair address matching circuit 14 is configured to receive the latched address Latch FA[n:0] and the undo flag signal Undo flag, lock an output soft repair matching signal SPPR Match into an inactive level when the undo flag signal Undo flag is at an active level, and match a target address RA[n:0] with the latched address Latch FA[n:0] to generate and output the soft repair matching signal SPPR Match when the undo flag signal Undo flag is at an inactive level; when the soft repair matching signal SPPR Match is at an active level, it is indicated that the target address RA[n:0] successfully matches the latched address Latch FA[n:0], and when the soft repair matching signal SPPR Match is at an inactive level, it is indicated that the target address RA[n:0] does not successfully match the latched address Latch FA[n:0]. The target address RA[n:0] is an address corresponding to an access operation in a normal operating mode.

Specifically, the latch control signal SPPR Latch can simultaneously control the outputs of the undo control circuit 12 and the soft repair address latch circuit 13 to implement a soft repair lock function, i.e., to lock the result of the executed soft repair operation (latched address Latch FA[n:0]) unchanged. Specifically, when the lock enable signal Lock En at an active level indicates the entry into the soft repair mode and the execution of the soft repair lock operation, the lock control circuit 11 may shield, based on the lock enable signal Lock En, the subsequently input soft repair pulse signal SPPR Clk, and lock the output latch control signal SPPR Latch into the first level. The latch control signal SPPR Latch at the first level may control the undo control circuit 12 to shield the subsequently input undo enable signal Undo En indicating the execution of the soft repair undo operation, so as to maintain the original output undo flag signal Undo flag unchanged. In addition, the latch control signal SPPR Latch at the first level may control the soft repair address latch circuit 13 to remain in a locked state, and no longer respond to the currently input and subsequently input soft repair fail addresses SPPR FA[n:0], thereby maintaining the currently latched soft repair fail address Latch FA[n:0] unchanged. At the same time, the latch control signal SPPR Latch may simultaneously control the matching result output by the soft repair address matching circuit 14 to implement the soft repair undo function, i.e., undo the previously executed soft repair operation, and shield/invalidate the matching result corresponding to the previously latched latched address Latch FA[n:0] in the normal operating mode. Specifically, when the undo enable signal Undo En at an active level indicates that the soft repair undo operation is executed, the undo control circuit 12 may output the undo flag signal Undo flag locked at an active level. Based on the undo flag signal Undo flag, the soft repair address matching circuit 14 may lock the output soft repair matching signal SPPR Match into an inactive level, indicating that the matching is unsuccessful and the soft repair operation is not executed regardless of the matching result of the latched address Latch FA[n:0]. In this case, it is equivalent to setting the latched address latched by the soft repair address latch circuit 13 into an inactive state, and setting the corresponding soft repair redundant row into an unusable state, i.e., undoing the previous soft repair operation. In this way, by using the newly added lock control circuit 11 and undo control circuit 12, as well as the lock control signal SPPR Latch output by the newly added lock control circuit 11 and the undo flag signal Undo flag output by the newly added undo control circuit, the soft repair control circuit 10 can complete a plurality of operations such as soft repair fail address latching, soft repair locking, and soft repair undo by controlling the original soft repair address latch circuit 13 and soft repair address matching circuit 14. On the premise of implementing various soft repair functions specified in the standard, the circuit design is simplified, thereby saving the circuit area.

Here, “maintaining the output unchanged” in the undo control circuit 12 and the soft repair address latch circuit 13 refers to locking the original output, i.e., maintaining the original level state of the output signal unchanged. For example, when the lock enable signal Lock En is at an active level, indicating that the soft repair lock operation is executed, even if the undo enable signal Undo En indicating the execution of the soft repair undo operation is subsequently received, the undo control circuit 12 cannot generate the undo flag signal Undo flag at an active level in response to the signal, but maintains the undo flag signal Undo flag at the original level state. That is, in the soft repair control circuit according to the embodiments of the present disclosure, the soft repair lock operation takes precedence over the soft repair undo operation. Specifically, if the lock enable signal Lock En indicating the execution of the soft repair lock operation arrives first, in this case, based on the lock control signal SPPR Latch at the first level, the subsequent undo enable signal Undo En indicating the execution of the soft repair undo operation will be shielded/ignored, and the corresponding soft repair undo operation will also not be executed. If the undo enable signal Undo En indicating the execution of the soft repair undo operation arrives first, followed by the lock enable signal Lock En indicating the execution of the soft repair lock operation, since the preceding undo enable signal Undo En has set the undo flag signal Undo flag to an active level, in this case, the lock control signal SPPR Latch at the first level will maintain the original level state (i.e., the active level) of the undo flag signal Undo flag output by the undo control circuit 12 unchanged. As a result, the soft repair control circuit 10 may still continue to execute the soft repair undo operation based on the undo flag signal Undo flag, i.e., the soft repair undo operation and the soft repair lock operation may be executed simultaneously.

In addition, if the latch control signal SPPR Latch is the inverted delayed signal of the soft repair pulse signal SPPR Clk, the pulse that is also present on the latch control signal SPPR Latch will switch between a high level (logic “1”) and a low level (logic “0”). Taking an example in which the pulse on the soft repair pulse signal SPPR Clk is a positive pulse for illustration, the pulse on the latch control signal SPPR Latch is a negative pulse. During the period when the pulse signal is at a low level (logic “0”), the soft repair address latch circuit 13 may “pass through” the input soft repair fail address SPPR FA[n:0] as the output latched address Latch FA[n:0], and then, during the period when the pulse signal is at a high level (logic “1”), the soft repair address latch circuit may latch the output latched address Latch FA[n:0]. However, If the lock enable signal is at an active level, the lock control circuit 11 will lock the latch control signal SPPR Latch at a first level (e.g., a high level, logic “1”). In this case, the soft repair address latch circuit 13 maintains the latched state based on the high-level (logic “1”) latch control signal SPPR Latch and does not “pass through” the currently input soft repair fail address SPPR FA[n:0]. The latch control signal SPPR Latch has a certain delay relative to the soft repair pulse signal SPPR Clk. This delay aims to ensure that the lock control circuit 11 has sufficient time to determine the states of the input lock enable signal Lock En, the soft repair activation signal SPPR ACT, and the soft repair pulse signal SPPR Clk, thereby determining to output the correct latch control signal SPPR Latch.

Here, the pulse on the soft repair pulse signal SPPR Clk may be a positive pulse or a negative pulse, and the first level may be a high level (logic “1”) or a low level (logic “0”). In the embodiments of the present disclosure, an example in which the pulse on the soft repair pulse signal SPPR Clk is a positive pulse and the first level is a high level (logic “1”) is used for illustration, but does not constitute a specific limitation to the embodiments of the present disclosure.

It should be noted that in the embodiments of the present disclosure, the active levels of different signals may vary. For example, the lock enable signal Lock En, the undo enable signal Undo En, the soft repair activation signal SPPR ACT, and the soft repair matching signal SPPR Match may use a high level (logic “1”) as the active level and a low level (logic “0”) as the inactive level. Meanwhile, the undo flag signal Undo flag may use a low level (logic “0”) as the active level and a high level (logic “1”) as the inactive level. In some other embodiments, the active levels of the above signals may also be other level combinations, which is not limited here.

It should be further noted that the soft repair operation of the memory may be replacing a faulty memory row with a soft repair redundant row in the bank. In this case, the soft repair fail address SPPR FA[n:0], the latched address Latch FA[n:0], and the target address RA[n:0] are all row addresses. In some other embodiments, the soft repair operation of the memory may also be replacing a faulty memory column with a soft repair redundant column in the bank. In this case, the soft repair fail address SPPR FA[n:0], the latched address Latch FA[n:0], and the target address RA[n:0] are all column addresses.

It should be further noted that although the above operations executed by the lock control circuit 11, the undo control circuit 12, and the soft repair address latch circuit 13 are completed in the soft repair mode (the soft repair mode will be entered upon receiving a soft repair command transmitted by the memory controller, indicating the execution of operations such as soft repair write, soft repair undo, and soft repair lock), the latch control signal SPPR Latch, the undo flag signal Undo flag, and the latched address Latch FA[n:0] output by these circuits may maintain unchanged when the soft repair mode is exited, that is, the current soft repair operation may still influence other subsequent operations even after its completion. The latch control signal SPPR Latch locked into the first level may shield other subsequent soft repair operations, including a soft repair write operation and a soft repair undo operation. The corresponding latched address Latch FA[n:0] maintains unchanged and is not overwritten by a subsequently input soft repair fail address. The undo flag signal Undo flag at an active level may shield the matching result between the corresponding latched address Latch FA[n:0] and the target address RA[n:0] in the subsequent normal operating mode, the soft repair matching signal SPPR Match indicating that the matching is unsuccessful is output, and the corresponding soft repair redundant row is set to an unusable state. If the undo flag signal Undo flag is at an inactive level, the latched address Latch FA[n:0] may match the target address RA[n:0] in the soft repair address matching circuit 14 in the subsequent normal operating mode. When the matching is successful, the soft repair matching signal SPPR Match at an active level is output to indicate the activation of a word line of a corresponding soft repair redundant row, thereby achieving the purpose of soft repair.

The embodiments of the present disclosure relate to an overall framework design of the soft repair control circuit, and in particular, to a DRAM DDR5 chip. The overall framework design may also be applied to other DDR series chips and LPDDR series chips, but is not limited to this scope. Other memory chips, other internal repair circuits, and the like may all adopt this design.

Further, for the composition of the lock control circuit 11, as shown in FIG. 2, the lock control circuit 11 includes: a lock-flag signal generation circuit 111 and a latch control signal generation circuit 112. The lock-flag signal generation circuit is configured to receive the lock enable signal Lock En, the soft repair activation signal SPPR ACT, and the soft repair pulse signal SPPR Clk, generate and output the latch control signal SPPR Latch at an active level in response to a pulse on the soft repair pulse signal SPPR Clk when the lock enable signal Lock En is at an active level and the soft repair activation signal SPPR ACT is at an active level, and generate and output a lock-flag signal Lock flag at an inactive level when the lock enable signal Lock En is at an inactive level. The latch control signal generation circuit is configured to receive the lock-flag signal Lock flag, the soft repair activation signal SPPR ACT, and the soft repair pulse signal SPPR Clk, lock the output latch control signal SPPR Latch into the first level when the lock-flag signal Lock flag is at an active level, and output the inverted delayed signal of the soft repair pulse signal SPPR Clk as the latch control signal SPPR Latch when the lock-flag signal Lock flag is at an inactive level and the soft repair activation signal SPPR ACT is at an active level.

Here, the lock-flag signal Lock flag output by the lock-flag signal generation circuit 111 is required to control whether the latch control signal generation circuit 112 shields the input soft repair pulse signal SPPR Clk. However, as the lock-flag signal generation circuit 111 processes all the input signals (the lock enable signal Lock En, the soft repair activation signal SPPR ACT, and the soft repair pulse signal SPPR Clk) to generate the lock-flag signal Lock flag, the output lock-flag signal Lock flag at an active level is later than the corresponding soft repair pulse signal SPPR Clk. Therefore, the soft repair pulse signal SPPR Clk is required to be subjected to an inverted delayed operation to ensure that the lock-flag signal Lock flag at an active level output by the lock-flag signal generation circuit 111 may be earlier than the inverted delayed signal of the soft repair pulse signal SPPR Clk. In addition, the soft repair pulse signal is shielded to ensure that the latch control signal SPPR Latch output when the lock-flag signal Lock flag is at an active level is constant at the first level.

It should be noted that in the embodiments of the present disclosure, an example in which the active level of the lock-flag signal Lock flag is a high level (logic “1”), and the inactive level of the lock-flag signal is a low level (logic “0”) is used for illustration, but does not constitute a specific limitation to the embodiments of the present disclosure.

In an embodiment of the present disclosure, referring to FIG. 3, the lock-flag signal generation circuit 111 includes: a first NAND gate 1111 and a D flip-flop 1112. The input terminals of the first NAND gate 1111 receive the lock enable signal Lock En, the soft repair activation signal SPPR ACT, and the soft repair pulse signal SPPR Clk separately. The input terminal of the D flip-flop 1112 is electrically connected to a power supply terminal VDD, the clock terminal of the D flip-flop 1112 is electrically connected to the output terminal of the first NAND gate 1111, and the output terminal of the D flip-flop 1112 is configured to output the lock-flag signal Lock flag. The latch control signal generation circuit 112 includes: a delay unit 1121, a second NAND gate 1122, and an OR gate 1123. The input terminal of the delay unit 1121 receives the soft repair pulse signal SPPR Clk. A first input terminal of the second NAND gate 1122 receives the soft repair activation signal SPPR ACT, and a second input terminal of the second NAND gate 1122 is electrically connected to the output terminal of the delay unit 1121. A first input terminal of the OR gate 1123 is electrically connected to the output terminal of the D flip-flop 1112, a second input terminal of the OR gate 1123 is electrically connected to the output terminal of the second NAND gate 1122, and the output terminal of the OR gate 1123 is configured to output the latch control signal SPPR Latch.

Here, referring to FIG. 3, when both the lock enable signal Lock En and the soft repair activation signal SPPR ACT are at an active level (high level), the first NAND gate 1111 outputs a negative pulse in response to a positive pulse on the soft repair pulse signal SPPR Clk, and the clock terminal CK of the D flip-flop 1112 outputs the power supply voltage VDD (high level) of the input terminal D to the output terminal Q in response to the rising edge of the negative pulse (i.e., the falling edge of the positive pulse on the soft repair pulse signal SPPR Clk), that is, the lock-flag signal Lock flag is set to an active level (high level), and the time when the lock-flag signal Lock flag transitions to an active level is later than the falling edge of the positive pulse on the soft repair pulse signal SPPR Clk. Meanwhile, in the latch control signal generation circuit 112, by using the delay unit 1121, the positive pulse on the pulse delay signal ClkD may be later than the positive pulse on the soft repair pulse signal SPPR Clk, and in this case, the negative pulse signal output by the second NAND gate 1122 is also later than the time when the lock-flag signal Lock flag transitions to an active level, thereby ensuring that the lock-flag signal Lock flag at an active level may shield the negative pulse output by the second NAND gate 1122 (i.e., the positive pulse on the soft repair pulse signal SPPR Clk) through the OR gate 1123. That is, when the lock enable signal Lock En is active, the output latch control signal SPPR Latch may be controlled to remain in a latched state at the first level (high level) without generating pulses, so as to control the soft repair address latch circuit 13 to hold the currently output latched address Latch FA[n:0] and control the undo control circuit 12 to maintain the currently output undo flag signal Undo flag unchanged, thereby achieving the purpose of executing the soft repair lock operation.

In some embodiments of the present disclosure, the reset terminal of the D flip-flop 1112 further receives a reset signal reset, and sets the output terminal to a low level (logic “0”) in response to a power-on reset signal reset. The reset signal may be a power-on reset signal, or may be a disabling reset signal generated when an HPPR, MBIST, or MPPR function is enabled.

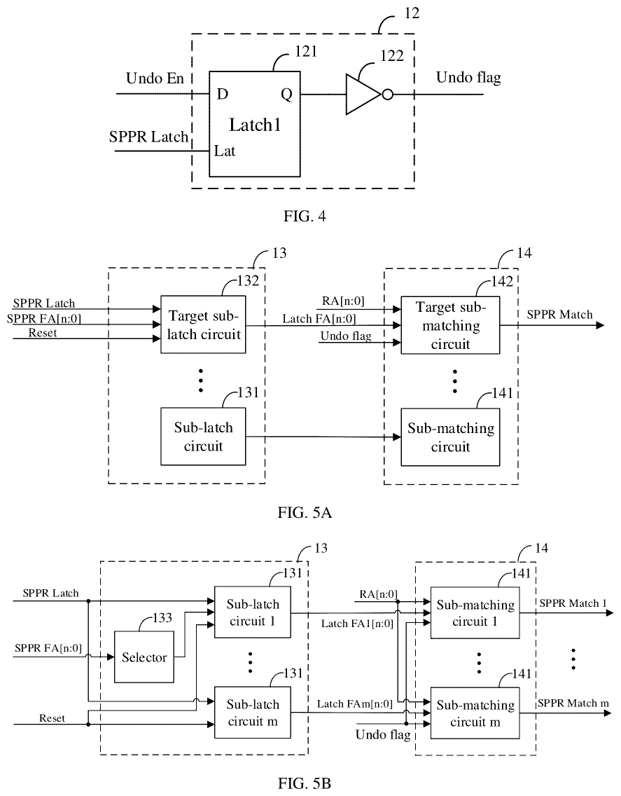

In an embodiment of the present disclosure, referring to FIG. 4, the undo control circuit 12 includes: a first latch 121 and a NOT gate 122. The input terminal of the first latch 121 receives the undo enable signal Undo En, and the control terminal of the first latch 121 receives the latch control signal SPPR Latch. The input terminal of the NOT gate 122 is electrically connected to the output terminal of the first latch 121, and the output terminal of the NOT gate 122 is configured to output the undo flag signal Undo flag.

Specifically, with reference to FIGS. 3 and 4, when the latch control signal SPPR Latch is the inverted delayed signal of the soft repair pulse signal SPPR Clk, i.e., when a negative pulse is present on the latch control signal SPPR Latch and the latch control signal SPPR Latch received by the control terminal Lat of the first latch 121 is at a low level, the first latch 121 is in a “pass-through” state, and the undo enable signal Undo En of the input terminal D is transmitted to the output terminal Q. When the undo enable signal Undo En is at an active level (high level), the signal output to the input terminal of the NOT gate 122 by the output terminal Q of the first latch 121 is at a high level, and the lock-flag signal Undo flag output by the NOT gate 122 is at an active level (low level). When the latch control signal SPPR Latch received by the control terminal Lat of the first latch 121 transitions to a high level, the first latch 121 is in a “latched” state, the signal output by the output terminal Q is locked at a high level, and the lock-flag signal Undo flag output by the NOT gate 122 remains at an active level (low level). When the latch control signal SPPR Latch is locked into the first level (high level), the first latch 121 remains at an initial low level, and the lock-flag signal Undo flag correspondingly output by the NOT gate 122 remains at an inactive level (high level). Here, an example in which the active level of the undo enable signal Undo En is a high level (logic “1”), and the active level of the lock-flag signal Undo flag is a low level (logic “0”) is used for illustration.

In some embodiments of the present disclosure, the first latch 121 may be a D latch. The reset terminal of the first latch 121 receives a reset signal reset, and sets the output terminal to 0 in response to the reset signal reset.

In an embodiment of the present disclosure, referring to FIG. 5A, the soft repair address latch circuit 13 includes at least one sub-latch circuit 131. One sub-latch circuit 131 serves as a target sub-latch circuit 132. The target sub-latch circuit 132 is configured to receive the latch control signal SPPR Latch and the soft repair fail address SPPR FA[n:0], maintain the currently output latched address Latch FA[n:0] unchanged when the latch control signal SPPR Latch is locked into the first level, and latch the soft repair fail address SPPR FA[n:0] into the latched address Latch FA[n:0] in response to a pulse on the latch control signal SPPR Latch when the latch control signal SPPR Latch is the inverted delayed signal of the soft repair pulse signal SPPR Clk.

In some embodiments of the present disclosure, the soft repair address latch circuit 13 includes one sub-latch circuit 131. In this case, there is no need to select the target sub-latch circuit 132, and the one sub-latch circuit 131 may be configured for soft post package repair SPPR to latch the corresponding soft repair fail address SPPR FA[n:0].

In some embodiments, the soft repair address latch circuit 13 includes a plurality of sub-latch circuits 131. In this case, one of the plurality of sub-latch circuits 131 is required to be selected as the target sub-latch circuit 132. One target sub-latch circuit 132 may be selected in order to receive the latch control signal SPPR Latch and the soft repair fail address SPPR FA[n:0]. Alternatively, a select circuit (not shown) may be provided. According to related configuration signals, the select circuit is controlled to select and enable one sub-latch circuit 131 as the target sub-latch circuit 132 and transmit the latch control signal SPPR Latch and the soft repair fail address SPPR FA[n:0] to the enabled sub-latch circuit 131 (i.e., the target sub-latch circuit 132).

It should be noted that the HPPR and the SPPR may share the plurality of sub-latch circuits 131 in the soft repair address latch circuit 13 and corresponding soft repair redundant row resources in the bank. In addition to the one sub-latch circuit 131 selected as the target sub-latch circuit 132, the remaining sub-latch circuits 131 may all be configured to perform latching on the hard repair fail address in the hard post package repair HPPR.

In some embodiments of the present disclosure, as shown in FIG. 5B, the soft repair address latch circuit 13 further includes a selector 133, the target sub-latch circuit 132, and an unselected sub-latch circuit 131. The selector is configured to receive the soft repair fail address SPPR FA[n:0], select one sub-latch circuit 131 as the target sub-latch circuit 132 according to a preset order during each soft repair operation, and transmit the soft repair fail address SPPR FA[n:0] to the target sub-latch circuit 132. The target sub-latch circuit is configured to receive the latch control signal SPPR Latch and the soft repair fail address SPPR FA[n:0], maintain the currently output latched address Latch FA[n:0] unchanged when the latch control signal SPPR Latch is locked into the first level, and latch the soft repair fail address SPPR FA[n:0] into the latched address Latch FA[n:0] in response to a pulse on the latch control signal SPPR Latch when the latch control signal SPPR Latch is the inverted delayed signal of the soft repair pulse signal SPPR Clk. The unselected sub-latch circuit fails to receive the soft repair fail address SPPR FA[n:0] and maintains the previously output latched address unchanged despite receiving the latch control signal SPPR Latch.

In some embodiments of the present disclosure, the target sub-latch circuit 131 receives a reset signal reset, and sets the output terminal to 0 in response to the reset signal reset. That is, the latched address Latch FA[n:0] is 000 . . . 00. In this case, an all-0 address signal is not used in the bank to identify the memory row.

In some embodiments of the present disclosure, as shown in FIG. 5A, the soft repair address matching circuit 14 includes at least one sub-matching circuit 141. The at least one sub-matching circuit 141 is connected to the at least one sub-latch circuit 131 in a one-to-one correspondence manner, and one sub-matching circuit correspondingly connected to the target sub-latch circuit 132 serves as a target sub-matching circuit 142. The target sub-matching circuit 142 is configured to receive the undo flag signal Undo flag and the target address RA[n:0], lock the output soft repair matching signal SPPR Match into an inactive level when the undo flag signal Undo flag is at an active level, and match a corresponding latched address Latch FA[n:0] with the target address RA[n:0] to generate and output a corresponding soft repair matching signal SPPR Match when the undo flag signal Undo flag is at an inactive level.

Here, the target address RA[n:0] is address information corresponding to an access operation in the normal operating mode, and the target sub-matching circuit 142 and other sub-matching circuits 141 receive the target address RA[n:0] and perform a matching function on the target address in the normal operating mode. In some embodiments, both the target sub-matching circuit 142 and other sub-matching circuits 141 are enabled in the normal operating mode, and are disabled in the soft repair mode and other repair modes, thereby further reducing the power consumption of the memory in the soft repair mode.

It should be noted that in addition to the target sub-matching circuit 142, other sub-matching circuits 131 are connected to corresponding sub-latch circuits 131. These sub-latch circuits 131 are not selected to latch the soft repair fail address SPPR FA[n:0] during the soft repair operation, but are configured to latch other failed addresses in a repair process such as HPPR/MPPR. Therefore, these sub-matching circuits 131 are also configured to receive the target address RA[n:0], and match the target address RA[n:0] with other failed addresses received by the sub-matching circuits to output a matching signal, except that the matching signal does not correspond to the soft repair redundant row, but points to a redundant row corresponding to other repair operations such as HPPR/MPPR after being decoded by the row address decoding circuit.

In some embodiments of the present disclosure, as shown in FIG. 5B, the soft repair address matching circuit 14 includes at least one sub-matching circuit 141. The at least one sub-matching circuit 141 is connected to the at least one sub-latch circuit 131 in a one-to-one correspondence manner. Each sub-matching circuit 141 is configured to receive the undo flag signal Undo flag and the target address RA[n:0], lock the correspondingly output soft repair matching signal SPPR Match into an inactive level when the undo flag signal Undo flag is at an active level, and match the latched address Latch FA[n:0] output by the corresponding sub-latch circuit 131 with the target address RA[n:0] to generate and output one corresponding soft repair matching signal SPPR Match when the undo flag signal Undo flag is at an inactive level.

Here, all the sub-latch circuits 131 are configured for soft repair and correspondingly latch one repair failed address. All the sub-matching circuits 141 receive the target address RA[n:0] and match the target address with the soft repair fail address output by the corresponding sub-latch circuit 131, and output a corresponding soft repair matching signal to point to a corresponding soft repair redundant row. That is, each of the sub-matching circuits 141 corresponds to one soft repair redundant row. Specifically, with reference to FIGS. 5B and 7, the soft repair address latch circuit 13 includes m sub-latch circuits 131, and the corresponding soft repair address matching circuit 14 also includes m sub-matching circuits 141, where m is an integer greater than or equal to 1. Each of the m sub-latch circuits 131 corresponds to one soft repair redundant row in a bank BA. Specifically, a sub-matching circuit i receives the undo flag signal Undo flag, the target address RA[n:0], and the latched address Latch FAi[n:0] output by a corresponding one of the m sub-latch circuits 131 (i.e., a latched soft repair fail address SPPR FAi[n:0], i being an integer greater than or equal to 1 and less than or equal to m). When the undo flag signal Undo flag is at an active level, the output soft repair matching signal SPPR Match i is locked into an inactive level, and when the undo flag signal Undo flag is at an inactive level, the latched address Latch FAi[n:0] matches the target address RA[n:0]. When the matching is successful, an active soft repair matching signal SPPR Match i may be transmitted to a row address decoding circuit 30, and the target address RA[n:0] is linked to the i-th soft repair redundant row corresponding to the soft repair matching signal SPPR Match i (the sub-matching circuit i) through the row address decoding circuit 30. That is, the failed memory row corresponding to the soft repair fail address SPPR FAi[n:0] is replaced with one soft repair redundant row, thereby achieving the purpose of performing the soft repair on the failed memory row in the bank.

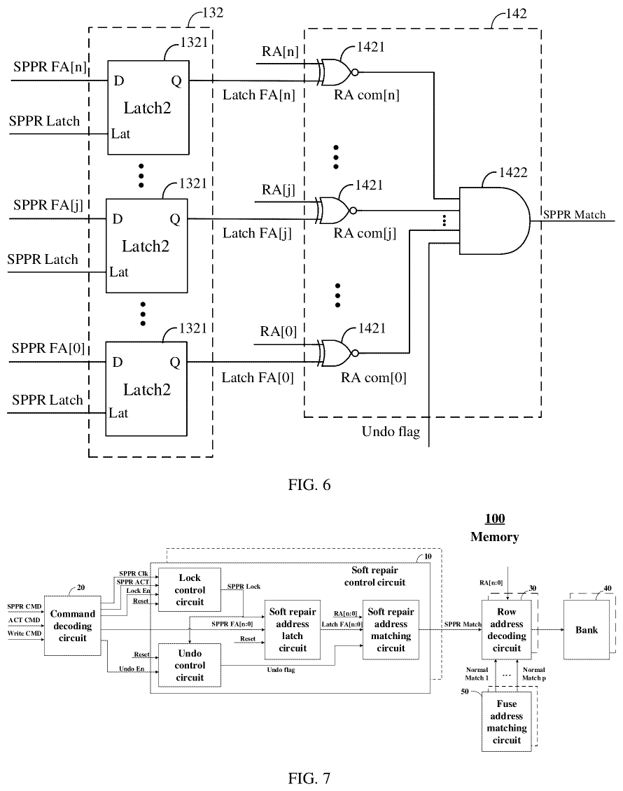

Further, with respect to the circuit structures of the target sub-latch circuit 132 and the target sub-matching circuit 142, as shown in FIG. 6, the target sub-latch circuit 132 includes a plurality of second latches 1321. The plurality of second latches 1321 are in one-to-one correspondence with a plurality of first address signals in the soft repair fail address SPPR FA[n:0] and a plurality of second address signals in the latched address Latch FA[n:0]. The input terminal of each of the plurality of second latches 1321 receives a corresponding one of the plurality of first address signals, the control terminal of the second latch 1321 receives the latch control signal SPPR Latch, and the output terminal of the second latch 1321 is configured to output a corresponding one of the plurality of second address signals.

Here, the plurality of second latches 1321 in the target sub-latch circuit 132 perform bit-by-bit latching on the input soft repair fail address SPPR FA[n:0] under the control of the latch control signal SPPR Latch. Specifically, the input terminal D of the j-th second latch 1321 receives the j-th first address signal SPPR FA[j−1], j being a positive integer less than or equal to n+1. The control terminal Lat of the j-th second latch 1321 receives the latch control signal SPPR Latch, “passes through” the j-th first address signal SPPR FA[j−1] received by the input terminal D to the output terminal Q as the j-th second address signal Latch FA [j−1] when the latch control signal SPPR Latch is at a low level (logic “0”), and latches the j-th second address signal Latch FA [j−1] of the output terminal Q when the latch control signal SPPR Latch is at a high level (logic “1”).

In some embodiments of the present disclosure, the second latch 1321 may be a D latch. The reset terminal of the second latch 1321 receives a reset signal reset, and sets the output terminal to 0 in response to the reset signal reset.

With continued reference to FIG. 6, the target sub-matching circuit 142 includes a plurality of exclusive NOR gates 1421 and an AND gate 1422. The plurality of exclusive NOR gates 1421 are in one-to-one correspondence with the plurality of second latches 1321 and a plurality of third address signals in the target address RA[n:0]. The first input terminal of each of the plurality of exclusive NOR gates 1421 receives a corresponding one of the plurality of third address signals, and a second input terminal of the exclusive NOR gate 1421 is electrically connected to the output terminal of a corresponding one of the plurality of second latches 1321. One input terminal of the AND gate 1422 receives the undo flag signal Undo flag, other input terminals of the AND gate 1422 are electrically connected to the output terminals of the plurality of exclusive NOR gates 1421 in a one-to-one correspondence manner, and the output terminal of the AND gate 1422 is configured to output the soft repair matching signal SPPR Match.

Here, the plurality of exclusive NOR gates 1421 in the target sub-matching circuit 142 are configured to perform bitwise comparison and matching on Latch FA [n:0] output by the plurality of second latches 1321 and the target address RA[n:0], and the AND gate 1422 outputs an active soft repair matching signal SPPR Match when the comparison results indicate that all address bits are the same. Specifically, the input terminals of the j-th exclusive NOR gate 1421 receive the j-th second address signal Latch FA [j−1] output by the i-th second latch 1321 and the j-th third address signal RA [j−1] separately. When the second address signal Latch FA [j−1] and the third address signal RA [j−1] are the same, the j-th exclusive NOR gate 1421 outputs a high-level comparison result RA com[j−1]. If all the comparison results RA com[n:0] of the plurality of exclusive NOR gates 1421 are at a high level and the undo flag signal Undo flag is at an inactive level (high level), the AND gate 1422 outputs an active soft repair matching signal SPPR Match, indicating that the matching is successful. When the undo flag signal Undo flag received by the AND gate 1422 is at an active level (low level), regardless of the comparison results RA com[n:0] of the plurality of exclusive NOR gates 1421, the AND gate 1422 outputs an inactive soft repair matching signal SPPR Match, indicating that the matching is unsuccessful. That is, the soft repair undo function is implemented.

In some embodiments of the present disclosure, as shown in FIG. 1, the lock control circuit 11 is further configured to reset the latch control signal SPPR Latch in response to a reset signal Reset; the undo control circuit 12 is further configured to reset the undo flag signal Undo flag to an inactive level in response to the reset signal Reset; the soft repair address latch circuit 13 is further configured to reset the latched address Latch FA[n:0] in response to the reset signal Reset.

Here, in response to the reset signal Reset, the lock control circuit 11, the undo control circuit 12, and the soft repair address latch circuit 13 are all restored to an initial unrepaired state. Specifically, the lock control circuit 11 resets the lock-flag signal Lock flag to an inactive level, and a corresponding latch control signal SPPR Latch is reset to a second level. The undo control circuit 12 resets the undo flag signal Undo flag to an inactive level, and the soft repair address latch circuit 13 resets the latched address Latch FA[n:0] to the second level. Here, an example in which the first level is a high level (logic “1”), the second level is a low level (logic “0”), the active level is a high level (logic “1”), and the inactive level is a low level (logic “0”) is used for illustration.

It should be noted that the reset signal Reset may be a power-on reset signal, or may be a disabling reset signal generated when the HPPR, memory built-in self-test (memory built-in self-test, MBIST), or MBIST Post Package Repair (MPPR) function is enabled. In some embodiments, HPPR and SPPR share the soft repair address latch circuit 13 and corresponding soft repair redundant row resources in the bank, and the HPPR and SPPR functions cannot be enabled at the same time. Therefore, if the DRAM supports an optional SPPR undo/lock function, before entering the HPPR or MPPR mode, the SPPR must be disabled, cleared, and unlocked first. In this case, a disabling reset signal is required to reset the lock control circuit 11, the undo control circuit 12, and the soft repair address latch circuit 13.

It should be further noted that the features disclosed in the soft repair control circuit according to the above embodiments can be combined arbitrarily without conflict, and a new soft repair control circuit embodiment can be obtained.

The embodiments of the present disclosure further provide a memory. Referring to FIG. 7, the memory 100 includes a command decoding circuit 20 and the soft repair control circuit 10 according to the above embodiments. The command decoding circuit 20 is configured to receive a soft repair command SPPR CMD, and generate an undo enable signal Undo En at an active level when a soft repair mode parameter in the soft repair command SPPR CMD is a second preset value; and generate a lock enable signal Lock En at an active level when the soft repair mode parameter in the soft repair command SPPR CMD is a third preset value. The soft repair control circuit 10 is further configured to receive the undo enable signal Undo En and the lock enable signal Lock En, and control to execute a soft repair undo operation when the undo enable signal Undo En is at an active level; and control to execute a soft repair lock operation when the lock enable signal Lock En is at an active level.

Here, the soft repair command SPPR CMD may be a mode register write (mode register write, MRW) command. That is, the command decoding circuit 20 writes the soft repair mode parameter carried in the mode register write command MRW into a corresponding mode register MR23, for example, into MR23:OP[2:1], and generates and outputs a corresponding signal according to the soft repair mode parameter stored in the mode register MR23. Specifically, when the soft repair mode parameter MR23:OP[2:1] is a first preset value 01, a soft repair enable signal SPPR En at an active level is generated, which may indicate the entry into a soft repair mode, thereby executing a conventional soft repair write operation. When the soft repair mode parameter MR23:OP[2:1] is a second preset value 10, the undo enable signal Undo En at an active level is generated, which may indicate the execution of the soft repair undo operation. When the soft repair mode parameter MR23:OP[2:1] is a third preset value 11, the lock enable signal Lock En at an active level is generated, which may indicate the execution of the soft repair lock operation. When the soft repair mode parameter MR23:OP[2:1] is a fourth preset value 00 (the default initial value), the output soft repair enable signal SPPR En, undo enable signal Undo En, and lock enable signal Lock En are all set to an inactive level.

It should be noted that in the embodiments of the present disclosure, an example in which the active level of the soft repair enable signal SPPR En, the undo enable signal Undo En, and the lock enable signal Lock En is a high level (logic “1”), and the inactive level thereof is a low level (logic “0”) is used for illustration, but does not constitute a specific limitation to the embodiments of the present disclosure.

It should be further noted that the command decoding circuit 20 in the present disclosure may be applied to execute the decoding operation of the soft repair command, and may also be applied to execute the decoding operation of the access command and the decoding operation of other repair commands in the normal operating mode. In some other embodiments, the command decoding circuit 20 is applied to execute the decoding operation of the soft repair command, and the decoding circuits for executing the decoding operation of the access command and the decoding operation of other repair commands in the normal operating mode are respectively provided independently.

In some embodiments of the present disclosure, as shown in FIG. 7, the command decoding circuit 20 is further configured to generate a soft repair enable signal SPPR En at an active level when the soft repair mode parameter in the soft repair command SPPR CMD is a first preset value; when the soft repair enable signal SPPR En is at an active level, it is indicated that the memory 100 enters a soft repair mode. The command decoding circuit 20 is further configured to, after the memory 100 enters the soft repair mode, sequentially receive an activation command ACT CMD and a write command WRITE CMD, decode the activation command ACT CMD to generate and output a soft repair activation signal SPPR ACT and a soft repair fail address SPPR FA[n:0], and decode the write command WRITE CMD to generate and output a soft repair pulse signal SPPR Clk; when the address information carried in the activation command ACT CMD indicates a bank 40 corresponding to the soft repair control circuit 10, the soft repair activation signal SPPR ACT at an active level is generated and transmitted to the soft repair control circuit 10. The soft repair control circuit 10 is electrically connected to the command decoding circuit 20 and configured to receive the soft repair activation signal SPPR ACT, the soft repair fail address SPPR FA[n:0], and the soft repair pulse signal SPPR Clk, and latch the soft repair fail address SPPR FA[n:0] into a latched address Latch FA[n:0] according to the soft repair pulse signal SPPR Clk when the soft repair activation signal SPPR ACT is at an active level.

Here, the address information in the activation command ACT CMD includes bank group (bank group, BG) information, and bank (bank, BA) information. After the soft repair enable signal SPPR En at an active level indicates that the memory 100 enters the soft repair mode, the command decoding circuit 20 may decode the received activation command ACT CMD, and transmit the active soft repair activation signal SPPR ACT and the soft repair fail address SPPR FA[n:0] to the bank indicated by the BG/BA information to indicate the execution of the soft repair write operation on the fail address SPPR FA[n:0] of the target bank.

It should be noted that when the soft repair mode parameter MR23:OP[2:1] in the soft repair command SPPR CMD is the first preset value 01, the second preset value 10, or the third preset value 11, it can indicate that the memory 100 enters the soft repair mode, but the three soft repair mode parameters correspond to different soft repair operations being executed. Specifically, the soft repair mode parameter MR23:OP[2:1] of the first preset value 01 indicates the entry into the soft repair mode and the execution of a conventional soft repair write operation, where the soft repair write operation is to write a soft repair fail address SPPR FA[n:0] in a subsequently received activation command into a soft repair address latch circuit; the soft repair mode parameter MR23: OP[2:1] of the second preset value 10 indicates the entry into the soft repair mode and the execution of a soft repair undo operation; the soft repair mode parameter MR23:OP[2:1] of the third preset value 11 indicates the entry into the soft repair mode and the execution of a soft repair lock operation. In some embodiments, when the soft repair mode parameter MR23:OP[2:1] is the second preset value 10 or the third preset value 11, except for generating the corresponding undo enable signal Undo En and lock enable signal Lock En, the soft repair enable signal SPPR En is also generated to indicate the entry into the soft repair mode, so as to enable the activation command decoder 24 and the write command decoder 25, and execute the “conventional” soft repair write operation according to the subsequently received activation command ACT CMD and write command WRITE CMD, except that the undo enable signal Undo En and the lock enable signal Lock En will control to execute the soft repair undo operation and the soft repair lock operation with a higher priority, and the soft repair write operation corresponding to the soft repair enable signal SPPR En is ignored/shielded. In some other embodiments, when the soft repair mode parameter MR23:OP[2:1] is the second preset value 10 or the third preset value 11, the corresponding undo enable signal Undo En and lock enable signal Lock En are generated, and the soft repair enable signal SPPR En is not generated. In this case, the undo enable signal Undo En and the lock enable signal Lock En also indicate the decoding of the subsequently received activation command ACT CMD and write command WRITE CMD, except that the soft repair write operation is not executed, but the soft repair activation signal SPPR Act at an active level is transmitted to the target bank by using the bank group BG/bank BA information in the ACT CMD to enable the corresponding target bank to execute the soft repair undo operation and the soft repair lock operation. In this case, both the row address information in the activation command ACT CMD and the column address information in the write command WRITE CMD may be ignored, or the row address information in the activation command ACT CMD this time may be set to be the same as the row address information in the activation command ACT CMD when the soft repair mode was previously entered (for example, the soft repair fail address SPPR FA[n:0] in the conventional soft repair write operation when the soft repair mode parameter MR23:OP[2:1] is the first preset value 01).

It should be further noted that after receiving the soft repair command SPPR CMD indicating the entry into the soft repair mode, four consecutive MRW commands are further required to be received; an unexpected soft repair operation is prevented according to the protection key information carried in the MRW commands, thereby protecting data and repair resources in the bank. Specifically, the protection key information carried in the four MRW commands should be input in a specified order, and other MRW/R commands or non-MR commands (such as ACT, WR, and RD) are not allowed to interrupt the protection key sequence, such that the soft repair mode is allowed to be actually entered, thereby executing specific soft repair operations (such as a soft repair write operation, a soft repair undo operation, and a soft repair lock operation). However, if the protection key sequence is interrupted by a non-compliant command or the protection key is not entered in the specified order, the soft repair mode will not be actually entered to execute the soft repair operation.

In some embodiments of the present disclosure, with continued reference to FIG. 7, the memory 100 includes a plurality of banks 40 (identified by dashed boxes in the figure), and in a part of the memory, the plurality of banks BA are further grouped into one bank group BG. Each of the plurality of banks BA corresponds to one soft repair control circuit 10 and one soft repair activation signal SPPR ACT, and executes the soft repair operation independently according to the corresponding soft repair control circuit 10. However, which failed address in the bank 40 is targeted by each soft repair command to execute the soft repair operation is specified by enabling the corresponding soft repair activation signal SPPR ACT according to the bank address information in the activation command ACT CMD, including the bank group BG signal and the bank address BA signal. Specifically, an example in which the memory 100 includes eight bank groups BG0-BG7 and each of the bank groups includes four banks BA0-BA3 is used for illustration. 32 banks correspond to 32 soft repair control circuits and 32 soft repair activation signals SPPR ACT. When BG[2:0]=000 and BA[1:0]=00 in the received activation command ACT CMD, it is indicated that BA0 in the BG0 executes the current soft repair write operation, and the soft repair activation signal SPPR ACT corresponding to the bank is set to an active level and transmitted to the soft repair control circuit 10 corresponding to BG0-BA0, so as to indicate that various soft repair operations are executed according to the undo enable signal Undo En, the lock enable signal Lock En, the soft repair fail address SPPR FA[n:0], and the soft repair pulse signal SPPR Clk. In this case, 31 soft repair activation signals SPPR ACT corresponding to the remaining 31 banks are all at an inactive level, and none of the corresponding soft repair control circuits is enabled, such that the soft repair operation is not executed.

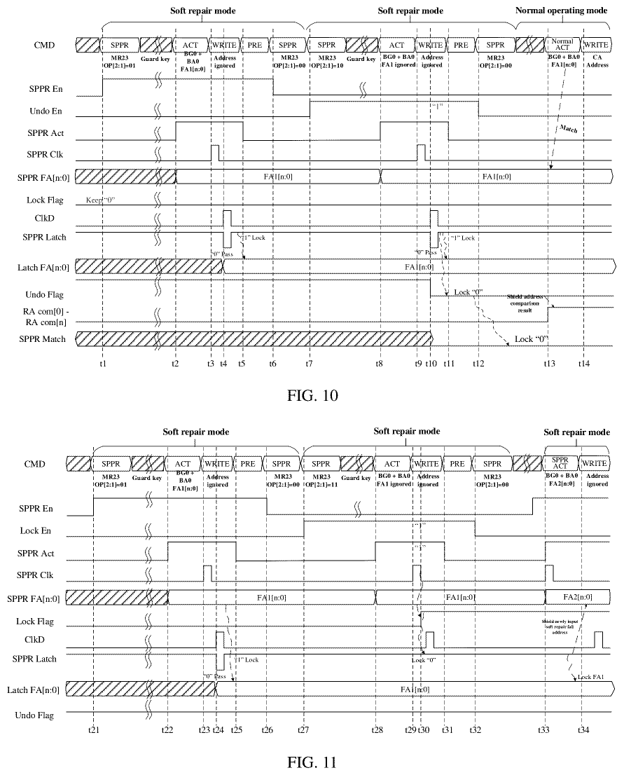

In some embodiments of the present disclosure, as shown in FIGS. 7 and 9, the memory 100 further includes a row address decoding circuit 30 and a bank 40. The command decoding circuit 20 is further configured to generate the soft repair enable signal SPPR En at an inactive level to indicate that the memory 100 enters a normal operating mode when the soft repair mode parameter in the soft repair command SPPR CMD is a fourth preset value. The command decoding circuit 20 is further configured to receive the activation command ACT CMD and decode the activation command ACT CMD to generate and output the target address RA[n:0] when the memory 100 is in the normal operating mode. The soft repair control circuit 10 is further configured to match the target address RA[n:0] with the latched address Latch FA[n:0] when the memory 100 is in the normal operating mode, and generate and output a soft repair matching signal SPPR Match at an active level when the target address RA[n:0] successfully matches the latched address Latch FA[n:0]. The row address decoding circuit 30 is electrically connected to the soft repair control circuit 10 and configured to receive the soft repair matching signal SPPR Match and the target address RA[n:0], and control to activate a word line of a corresponding soft repair redundant row SPPR RWL in the bank 40 according to the soft repair matching signal SPPR Match at an active level when the soft repair matching signal SPPR Match is at an active level.

Here, an example in which one sub-latch circuit 131 in each soft repair control circuit 10 is configured to latch the soft repair fail address, and one corresponding soft repair redundant row is present in the bank 40 is used for illustration. In some other embodiments, the plurality of sub-latch circuits 131 in the soft repair control circuit 10 may be configured to latch the soft repair fail address, and a plurality of soft repair redundant rows are also correspondingly present in the bank 40, which is not specifically limited herein.

It should be noted that when the soft repair mode parameter MR23:OP[2:1] in the soft repair command SPPR CMD is the fourth preset value 00, it is indicated that the soft repair mode is exited, i.e., the normal operating mode is entered. In this case the soft repair enable signal SPPR En is required to be set to an inactive level, and the undo enable signal Undo En and the lock enable signal Lock En are also required to be set to an inactive level.

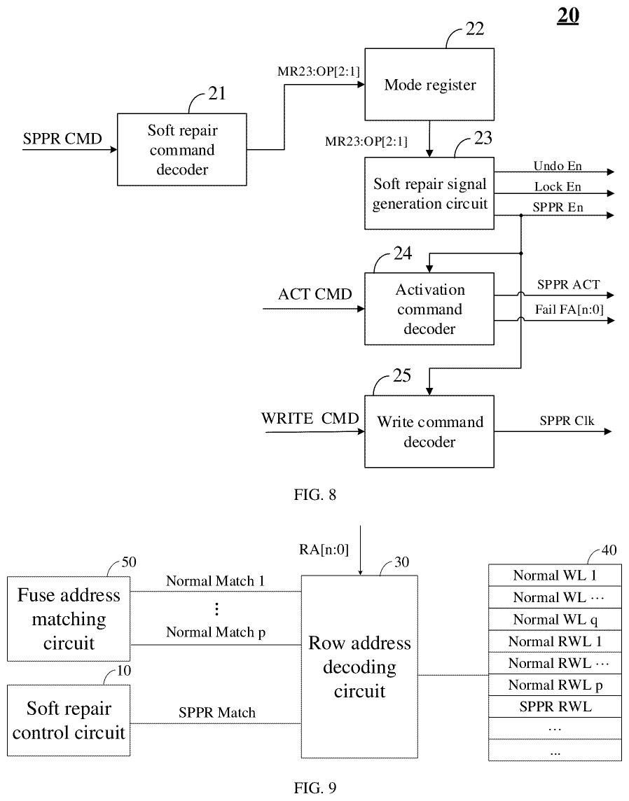

In some embodiments of the present disclosure, as shown in FIG. 8, the command decoding circuit 20 includes: a soft repair command decoder 21, a mode register 22, a soft repair signal generation circuit 23, an activation command decoder 24, and a write command decoder 25. The soft repair command decoder 21 is configured to receive the soft repair command SPPR CMD and write the soft repair mode parameter MR23:OP[2:1] in the soft repair command SPPR CMD into the mode register 22. The soft repair signal generation circuit 23 is configured to receive the soft repair mode parameter MR23:OP[2:1] stored in the mode register 22, and generate the soft repair enable signal SPPR En at an active level when the soft repair mode parameter MR23:OP[2:1] is the first preset value; generate the undo enable signal Undo En at an active level when the soft repair mode parameter MR23:OP[2:1] is the second preset value; and generate the lock enable signal Lock En at an active level when the soft repair mode parameter MR23:OP[2:1] is the third preset value. The activation command decoder 24 is configured to receive the soft repair enable signal SPPR En and the activation command ACT CMD, and decode the activation command ACT CMD to generate and output the soft repair activation signal SPPR ACT and the soft repair fail address SPPR FA[n:0] when the soft repair enable signal SPPR En at an active level indicates that the memory enters the soft repair mode. The write command decoder 25 is configured to receive the soft repair enable signal SPPR En and the write command WRITE CMD, and decode the write command WRITE CMD to generate and output the soft repair pulse signal SPPR Clk when the soft repair enable signal SPPR En at an active level indicates that the memory 100 enters the soft repair mode.

Here, the activation command decoder 24 is configured to decode the activation command ACT CMD after entering the soft repair mode, and the activation command ACT CMD received while the memory 100 is in the normal operating mode may be decoded by a normal activation command decoder (not shown) provided in the command decoding circuit 20. Both the activation command decoder 24 and the normal activation command decoder receive the activation command ACT CMD. When the soft repair enable signal SPPR En at an active level indicates that the memory 100 enters the soft repair mode, the activation command decoder 24 is enabled while the normal activation command decoder is disabled to ensure that only the soft repair activation signal SPPR ACT is output; when the soft repair enable signal SPPR En at an inactive level indicates that the memory 100 enters the normal operating mode, the normal activation command decoder is enabled while the activation command decoder 24 is disabled to ensure that only the normal activation signal ACT and the target address RA[n:0] are output.

In some embodiments of the present disclosure, as shown in FIGS. 7 and 9, the memory 100 further includes: a fuse address matching circuit 50. The fuse address matching circuit is configured to receive a plurality of standard failed addresses Normal FA[n:0] from a fuse array (not shown), match the received target address RA[n:0] with the plurality of standard failed addresses Normal FA[n:0] separately, and generate a plurality of standard matching signals Normal March 1-p according to matching results. The row address decoding circuit 30 is further configured to receive the plurality of standard matching signals Normal March 1-p, and control to activate a word line of a corresponding standard redundant row Normal RWL 1-p in the bank 40 according to the standard matching signal at an active level when any one of the plurality of standard matching signals is at an active level.

In some embodiments of the present disclosure, as shown in FIGS. 7 and 9, the row address decoding circuit 30 is further configured to control to activate a word line of a corresponding memory row Normal WL 1-q in the bank 40 according to the target address RA[n:0] when both the soft repair matching signal SPPR Match and the standard matching signal Normal March 1-p are at an inactive level.

FIGS. 10 and 11 are signal timing diagrams corresponding to a soft repair control circuit and a memory according to the embodiments of the present disclosure. Operating principles of the soft repair control circuit 10 and the memory 100 shown in FIGS. 1 to 9 are described with reference to FIGS. 10 and 11. Here, an example in which the active level of the soft repair enable signal SPPR En/the lock enable signal Lock En/the undo enable signal Undo En/the lock-flag signal Lock Flag/the soft repair activation signal SPPR ACT and the soft repair matching signal SPPR Match is a high level (logic “1”), the active level of the undo flag signal Undo flag may be a low level (logic “0”), and the first level is a high level (logic “1”) is used for illustration, but does not constitute a limitation to the embodiments of the present disclosure.

First, referring to FIG. 10, at the time t1, the soft repair command decoder 21 receives the soft repair command SPPR CMD and writes the soft repair mode parameter OP[2:1]=01 in the soft repair command SPPR CMD into the mode register MR23. Since the soft repair mode parameter OP[2:1] is the first preset value 01, the soft repair signal generation circuit 23 generates the soft repair enable signal SPPR En at an active level (high level) to indicate that the memory 100 enters the soft repair mode, and the activation command decoder 24 and the write command decoder 25 are enabled based on the soft repair enable signal SPPR En at an active level (high level).

Between the times t1 and t2, the memory 100 further needs to receive four consecutive MRW commands and formally enters the soft repair mode to execute the soft repair operation after verifying that the protection key information carried in the four consecutive MRW commands is correct. In some embodiments, the soft repair enable signal SPPR En at an active level (high level) may also be generated after verifying that the protection key information in the four consecutive MRW commands is correct.

At the time t2, the activation command decoder 24 receives the activation command ACT CMD. Since the soft repair enable signal SPPR En at an active level (high level) has enabled the activation command decoder 24, the activation command decoder 24 may decode the activation command ACT CMD to generate and output the soft repair activation signal SPPR ACT and the soft repair fail address SPPR FA[n:0]. Specifically, the bank for executing soft repair is determined according to the address information (BG/BA) in the activation command ACT CMD, and the soft repair activation signal SPPR ACT corresponding to the bank BG0/BA0 is set to an active level (high level) and transmitted to the corresponding soft repair control circuit 10. In addition, the row address information carried in the activation command ACT CMD is determined as the soft repair fail address FA1[n:0].

At the time t3, the write command decoder 25 receives the write command WRITE CMD. Since the soft repair enable signal SPPR En at an active level (high level) has enabled the write command decoder 25, the write command decoder 25 may decode the write command WRITE CMD to generate and output a soft repair pulse signal SPPR Clk with a positive pulse.

It should be noted that, in the soft repair mode, the column address does not need to be latched. Therefore, the column address information in the write command WRITE CMD may be ignored.

At the time t4, the delay unit 1121 in the soft repair control circuit 10 delays the soft repair pulse signal SPPR Clk to generate a pulse delay signal ClkD, where a positive pulse on the soft repair pulse signal SPPR Clk at the time t3 is delayed to a positive pulse on the pulse delay signal ClkD at the time t4. In addition, at this time, the lock enable signal Lock En received by the input terminal of the first NAND gate 1111 is at an inactive level (low level), the clock terminal of the D flip-flop 1112 maintains at a high level, the lock-flag signal Lock flag output by the D flip-flop 1112 maintains at an initial inactive level (low level), the latch control signal SPPR Latch output by the OR gate 1123 is equal to the output of the second NAND gate 1122, the soft repair activation signal SPPR ACT received by the second NAND gate 1122 has been set to a high level at the time t2, the output of the second NAND gate 1122 is opposite to the pulse delay signal ClkD, and the latch control signal SPPR Latch generates a negative pulse corresponding to the positive pulse on the pulse delay signal ClkD at the time t4.

At the same time, the input terminals D of the plurality of second latches 1321 in the soft repair control circuit 10 receive the soft repair fail address SPPR FA[n:0] before the time t4; the control terminals Lat of the plurality of second latches 1321 “pass through” the received soft repair fail address FA1[n:0] to the output terminals Q as the latched address Latch FA[n:0] according to the negative pulse (low level) generated by the latch control signal SPPR Latch at the time t4 and turn to a latched state when the negative pulse of the latch control signal SPPR Latch ends (changes to a high level), and the output FA1[n:0] is latched into a latched address.

At the time t5, a pre-charge command PRE CMD transmitted by the memory controller is received, and the soft repair activation signal SPPR Act is set to an inactive level (low level) based on the pre-charge command PRE CMD.

At the time t6, the soft repair command decoder 21 in the command decoding circuit 20 receives the soft repair command SPPR CMD. At this time, the soft repair mode parameter OP[2:1] in the soft repair command SPPR CMD is the fourth preset value 00, and the soft repair signal generation circuit 23 flips the soft repair enable signal SPPR En from an active level (high level) to an inactive level (low level) to indicate that the memory 100 exits the current soft repair mode (t1-t6), that is, the normal operating mode is entered.

At the time t7, the soft repair command decoder 21 receives a new soft repair command SPPR CMD, and at this time, the soft repair mode parameter OP[2:1] in the soft repair command SPPR CMD is the second preset value 10. The soft repair signal generation circuit 23 generates an undo enable signal Undo En at an active level (high level) and a soft repair enable signal SPPR En at an active level (high level) to indicate that the memory 100 enters the soft repair mode and executes the soft repair undo operation, and based on the soft repair enable signal SPPR En at an active level (high level), the activation command decoder 24 and the write command decoder 25 are also enabled.

At the time t8, the activation command decoder 24 receives the activation command ACT CMD, and the enabled activation command decoder 24 determines the bank for executing soft repair according to the address information (BG/BA) in the activation command ACT CMD, sets the soft repair activation signal SPPR ACT corresponding to the bank BG0/BA0 to an active level (high level), and transmits the same to the corresponding soft repair control circuit 10. In addition, the row address information carried in the activation command ACT CMD is determined as the soft repair fail address FA1[n:0].

It should be noted that after the soft repair command SPPR CMD (the soft repair mode parameter OP[2:1] carried therein is the second preset value 10 or the third preset value 11) indicating the execution of the soft repair undo operation and the soft repair lock operation, the address information (BG/BA/SPPR FA[n:0]) carried in the activation command ACT CMD needs to be the same as the address information carried in the activation command ACT CMD (at the time t2) after the last soft repair command SPPR CMD (the soft repair mode parameter OP[2:1] carried therein is the first preset value 00) indicating the execution of the soft repair write operation.

At the time t9, the write command decoder 25 receives the write command WRITE CMD, and the enabled write command decoder 25 may decode the write command WRITE CMD to generate and output a soft repair pulse signal SPPR Clk with a positive pulse.

At the time t10, the delay unit 1121 in the soft repair control circuit 10 delays the soft repair pulse signal SPPR Clk to generate a pulse delay signal ClkD, where a positive pulse on the soft repair pulse signal SPPR Clk at the time t9 is delayed to a positive pulse on the pulse delay signal ClkD at the time t10, and the latch control signal SPPR Latch generates a negative pulse corresponding to the positive pulse on the pulse delay signal ClkD at the time t10.

At the same time, the undo enable signal Undo En received by the input terminal of the first latch 121 in the undo control circuit 12 has been set to an active level (high level) at the time t7, and the control terminal Lat of the first latch 121 “passes through” the high-level signal of the input terminal D to the output terminal Q according to the negative pulse (low level) generated by the latch control signal SPPR Latch at the time t10 and turns to a latched state when the negative pulse of the latch control signal SPPR Latch ends (changes to a high level); the output terminal Q is latched into a high level (logic “1”), and the corresponding undo flag signal Undo Flag is locked at a low level (logic “0”). The plurality of second latches 1321 in the soft repair control circuit 10 also turn to a latched state when the negative pulse of the latch control signal SPPR Latch ends, and FA1[n:0] is latched into a latched address.

At the time t11, the soft repair activation signal SPPR Act is set to an inactive level (low level) according to the received pre-charge command PRE CMD.

At the time t12, according to the soft repair mode parameter OP[2:1] of the fourth preset value carried in the soft repair command SPPR CMD, the soft repair signal generation circuit 23 flips the soft repair enable signal SPPR En from an active level (high level) to an inactive level (low level) to indicate that the memory 100 exits the current soft repair mode (t7-t12).

At the time t13, the soft repair enable signal SPPR En at an inactive level indicates that the memory 100 is in the normal operating mode. The activation command ACT CMD received by the memory 100 at this time indicates the execution of a normal access operation (a read/write activation operation), and the memory 100 decodes the activation command ACT CMD to obtain the target address RA[n:0], that is, the row address FA1[n:0] corresponding to the current access operation. The plurality of exclusive NOR gates 1421 in the target sub-matching circuit 142 execute bitwise comparison between the target address RA[n:0] and the latched address Lock FA[n:0]; since both the target address RA[n:0] and the latched address Lock FA[n:0] are the row address FA1[n:0], comparison results RA com[0] to RA com[n] output by the plurality of exclusive NOR gates 1421 are all at a high level.

However, since the undo flag signal Undo Flag is set to an active level (low level) at the previous time t10, and there is no new soft repair command SPPR CMD to modify the same during t12 and t13, the undo flag signal Undo Flag still maintains at a low level. At this time, even if the comparison results RA com[0] to RA com[n] indicate that the soft-repaired latched address Lock FA[n:0] successfully matches the target address RA[n:0], the AND gate 1422 will also output the soft repair matching signal SPPR Match at an inactive level (low level), indicating that the matching is unsuccessful, that is, the soft repair undo function is achieved.

Still referring to FIG. 11, the timing during t21-t26 is the same as the timing during t1-t6 in FIG. 10. Reference is made to the foregoing contents for details and will not be repeated here.

At the time t27, the soft repair command decoder 21 receives a new soft repair command SPPR CMD, and at this time, the soft repair mode parameter OP[2:1] in the soft repair command SPPR CMD is the third preset value 11. The soft repair signal generation circuit 23 generates a lock enable signal Lock En at an active level (high level) and a soft repair enable signal SPPR En at an active level (high level) to indicate that the memory 100 enters the soft repair mode and executes the soft repair undo operation, and based on the soft repair enable signal SPPR En at an active level (high level), the activation command decoder 24 and the write command decoder 25 are also enabled.

At the time t28, the activation command decoder 24 receives the activation command ACT CMD, and the enabled activation command decoder 24 determines the bank for executing soft repair according to the address information (BG/BA) in the activation command ACT CMD, sets the soft repair activation signal SPPR ACT corresponding to the bank BG0/BA0 to an active level (high level), and transmits the same to the corresponding soft repair control circuit 10. In addition, the row address information carried in the activation command ACT CMD is determined as the soft repair fail address FA1[n:0].

At the time t29, the write command decoder 25 receives the write command WRITE CMD, and the enabled write command decoder 25 may decode the write command WRITE CMD to generate and output a soft repair pulse signal SPPR Clk with a positive pulse.

At the times t29 and t30, both the lock enable signal Lock En and the soft repair activation signal SPPR ACT received by the input terminals of the first NAND gate 1111 are at an active level, and the output signal of the first NAND gate 1111 is opposite to the soft repair pulse signal SPPR Clk, that is, a negative pulse output by the first NAND gate 1111 to the clock terminal CK of the D flip-flop 1112 corresponds to a positive pulse on the soft repair pulse signal SPPR Clk.

At the time t30, the clock terminal CK of the D flip-flop 1112 outputs the power supply voltage VDD (high level) of the input terminal D to the output terminal Q in response to the rising edge of the negative pulse (i.e., the falling edge of the positive pulse on the soft repair pulse signal SPPR Clk), that is, the lock-flag signal Lock flag is set to an active level (high level).

Subsequently, the positive pulse of the soft repair pulse signal SPPR Clk at the time t29 is delayed to the positive pulse on the pulse delay signal ClkD, which arrives later than the time t30. However, since the lock-flag signal Lock flag is already at an active level (high level), the latch control signal SPPR Latch output by the OR gate 1123 remains in a latched state of the first level (high level), the negative pulse (i.e., the positive pulse on the soft repair pulse signal SPPR Clk) output by the second NAND gate 1122 is shielded/filtered, and the target sub-latch circuit 132 maintains the currently output latched address Latch FA[n:0] unchanged.

At the time t31, the soft repair activation signal SPPR Act is set to an inactive level (low level) according to the received pre-charge command PRE CMD.

At the time t32, according to the soft repair mode parameter OP[2:1] of the fourth preset value carried in the soft repair command SPPR CMD, the soft repair signal generation circuit 23 flips the soft repair enable signal SPPR En from an active level (high level) to an inactive level (low level) to indicate that the memory 100 exits the current soft repair mode (t27-t32).

At the time t33, after the memory 100 receives the soft repair command SPPR CMD and enters the soft repair mode again, the activation command decoder 24 receives the activation command ACT CMD, and the enabled activation command decoder 24 determines the bank for executing soft repair according to the address information (BG/BA) in the activation command ACT CMD, sets the soft repair activation signal SPPR ACT corresponding to the bank BG0/BA0 to an active level (high level), and transmits the same to the corresponding soft repair control circuit 10. In addition, the row address information carried in the activation command ACT CMD is determined as a new soft repair fail address FA2[n:0].

At the time t34, the enabled write command decoder 25 receives the write command WRITE CMD, and the enabled write command decoder 25 may decode the write command WRITE CMD to generate and output a soft repair pulse signal SPPR Clk with a positive pulse. However, since the lock-flag signal Lock flag is set to an active level (high level) at the time t30 and remains in a high-level state until the reset signal Reset (power-on reset signal) arrives, the OR gate 1123 still shields the positive pulse on the soft repair pulse signal SPPR Clk at the time t34 and continues to remain the output latch control signal SPPR Latch in the latched state of the first level (high level). The target sub-latch circuit 132 maintains the currently latched latched address FA1[n:0] unchanged based on the latch control signal SPPR Latch remained at a high level, and no longer “passes through” and locks the newly input soft repair fail address FA2[n:0], that is, the soft repair lock function is achieved.

It should be noted that the features disclosed in the memory according to the above embodiments can be combined arbitrarily without conflict, and a new memory embodiment can be obtained. In addition, the related technical details of the soft repair control circuit mentioned in the foregoing embodiments are still valid in this embodiment and are not described herein again to reduce repetition.

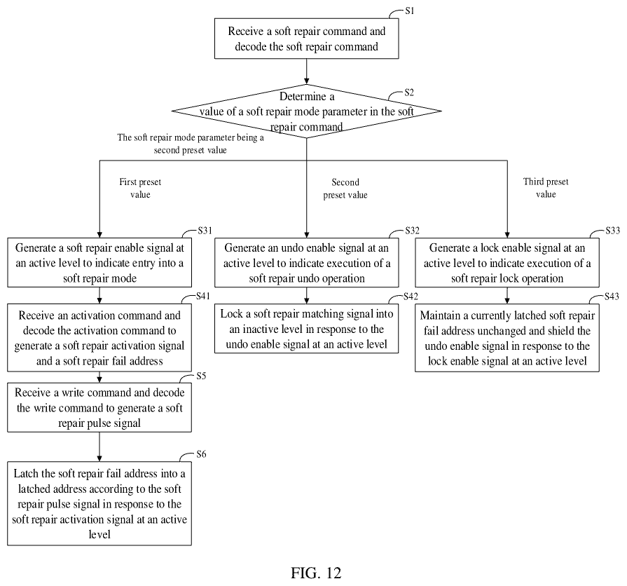

The embodiments of the present disclosure further provide a method for repairing a memory. Referring to FIG. 12, the method for repairing a memory includes the following steps.

In step S1, a soft repair command SPPR CMD is received, and the soft repair command SPPR CMD is decoded.

In step S2, the value of a soft repair mode parameter MR23:OP[2:1] in the soft repair command SPPR CMD is determined.

When the soft repair mode parameter is a second preset value, step S32 and step S42 are performed.

In step S32, an undo enable signal Undo En at an active level is generated to indicate the execution of a soft repair undo operation.

In step S42, in response to the undo enable signal Undo En at an active level, a soft repair matching signal SPPR Match is locked into an inactive level.

When the soft repair mode parameter is a third preset value, step S33 and step S43 are performed.

In step S33, a lock enable signal Lock En at an active level is generated to indicate the execution of a soft repair lock operation.

In step S43, in response to the lock enable signal Lock En at an active level, a currently latched soft repair fail address SPPR FA[n:0] is maintained unchanged, and the undo enable signal Undo En is shielded.

When the soft repair matching signal SPPR Match is at an inactive level, it is indicated that a target address RA[n:0] does not successfully match the latched soft repair fail address SPPR FA[n:0], where the target address RA[n:0] is an address corresponding to an access operation in a normal operating mode.

In some embodiments of the present disclosure, with continued reference to FIG. 12, the repair method further includes the following steps.

When the soft repair mode parameter is a first preset value, step S31 is performed.

In step S31, a soft repair enable signal SPPR En at an active level is generated to indicate the entry into a soft repair mode.

After the memory enters the soft repair mode, an activation command ACT CMD and a write command WRITE CMD are received sequentially, and step S41, step S5, and step S6 continue to be performed.

In step S41, the activation command ACT CMD is received, and the activation command ACT CMD is decoded to generate a soft repair activation signal SPPR ACT and a soft repair fail address SPPR FA[n:0].

In step S5, the write command WRITE CMD is received, and the write command WRITE CMD is decoded to generate a soft repair pulse signal SPPR Clk.

In step S6, in response to the soft repair activation signal SPPR ACT at an active level, the soft repair fail address SPPR FA[n:0] is latched into a latched address Latch FA[n:0] according to the soft repair pulse signal SPPR Clk.

In some embodiments of the present disclosure, the repair method further includes:
generating the soft repair enable signal SPPR En at an inactive level to indicate that the memory enters the normal operating mode when the soft repair mode parameter is a fourth preset value;
receiving the activation command ACT CMD and decoding the activation command ACT CMD to generate the target address RA[n:0] when the memory is in the normal operating mode;
matching the target address RA[n:0] with the latched soft repair fail address SPPR FA[n:0], and generating the soft repair matching signal SPPR Match at an active level when the matching is successful; and
controlling to activate a word line of a corresponding soft repair redundant row in the bank according to the soft repair matching signal SPPR Match at an active level.

It should be noted that the features disclosed in the method for repairing a memory according to the above embodiments can be combined arbitrarily without conflict, and a new repair method embodiment can be obtained. In addition, this embodiment can be implemented in cooperation with the bank and the soft repair control circuit according to the foregoing embodiments. The related technical details mentioned in the foregoing embodiments are still valid in this embodiment and are not described herein again to reduce repetition.

The above descriptions are merely exemplary embodiments of the present disclosure and are not intended to limit the protection scope of the present disclosure.

It should be noted that in the present disclosure, the terms “include”, “comprise”, or any other variants thereof are intended to cover non-exclusive inclusion, such that a process, a method, an item, or an apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The serial numbers of the embodiments of the present disclosure described above are for the purpose of describing only and do not represent the superiority or inferiority of the embodiments.

The above description is only the specific embodiments of the present disclosure, but the protection scope of the present disclosure is not limited thereto; changes or substitutions that any of those skilled in the art can easily think of within the technical scope disclosed by the present disclosure shall all fall within the protection scope of the present disclosure. Therefore, the protection scope of the present disclosure shall be subject to the protection scope of the claims.

What is claimed is:

1. A soft repair control circuit, comprising:
a lock control circuit, configured to receive a lock enable signal, a soft repair activation signal, and a soft repair pulse signal, lock an output latch control signal into a first level when the lock enable signal is at an active level, and output an inverted delayed signal of the soft repair pulse signal as the latch control signal in response to the soft repair activation signal at an active level when the lock enable signal is at an inactive level, wherein when the lock enable signal is at an active level, it is indicated that a soft repair lock operation is executed;
an undo control circuit, configured to receive an undo enable signal and the latch control signal, maintain an output unchanged when the latch control signal is locked into the first level, and generate and output an undo flag signal at an active level according to the undo enable signal at an active level in response to a pulse on the latch control signal when the latch control signal is the inverted delayed signal of the soft repair pulse signal, wherein when the undo enable signal is at an active level, it is indicated that a soft repair undo operation is executed;
a soft repair address latch circuit, configured to receive a soft repair fail address and the latch control signal, maintain an output unchanged when the latch control signal is locked into the first level, and latch the soft repair fail address and output the soft repair fail address as a latched address in response to a pulse on the latch control signal when the latch control signal is the inverted delayed signal of the soft repair pulse signal; and
a soft repair address matching circuit, configured to receive the latched address and the undo flag signal, lock an output soft repair matching signal into an inactive level when the undo flag signal is at an active level, and match a target address with the latched address to generate and output the soft repair matching signal when the undo flag signal is at an inactive level, wherein
when the soft repair matching signal is at an active level, it is indicated that the target address successfully matches the latched address, and when the soft repair matching signal is at an inactive level, it is indicated that the target address does not successfully match the latched address; and the target address is an address corresponding to an access operation in a normal operating mode.

2. The soft repair control circuit according to claim 1, wherein the lock control circuit comprises:
a lock-flag signal generation circuit, configured to receive the lock enable signal, the soft repair activation signal, and the soft repair pulse signal, generate and output the latch control signal at an active level in response to a pulse on the soft repair pulse signal when the lock enable signal is at an active level and the soft repair activation signal is at an active level, and generate and output a lock-flag signal at an inactive level when the lock enable signal is at an inactive level; and
a latch control signal generation circuit, configured to receive the lock-flag signal, the soft repair activation signal, and the soft repair pulse signal, lock the output latch control signal into the first level when the lock-flag signal is at an active level, and output the inverted delayed signal of the soft repair pulse signal as the latch control signal when the lock-flag signal is at an inactive level and the soft repair activation signal is at an active level.

3. The soft repair control circuit according to claim 2, wherein
the lock-flag signal generation circuit comprises:
a first NAND gate, wherein input terminals of the first NAND gate separately receive the lock enable signal, the soft repair activation signal, and the soft repair pulse signal; and
a D flip-flop, wherein an input terminal of the D flip-flop is electrically connected to a power supply terminal, a clock terminal of the D flip-flop is electrically connected to an output terminal of the first NAND gate, and an output terminal of the D flip-flop is configured to output the lock-flag signal; and
the latch control signal generation circuit comprises:
a delay unit, wherein an input terminal of the delay unit receives the soft repair pulse signal;
a second NAND gate, wherein a first input terminal of the second NAND gate receives the soft repair activation signal, and a second input terminal of the second NAND gate is electrically connected to an output terminal of the delay unit; and
an OR gate, wherein a first input terminal of the OR gate is electrically connected to the output terminal of the D flip-flop, a second input terminal of the OR gate is electrically connected to an output terminal of the second NAND gate, and an output terminal of the OR gate is configured to output the latch control signal.

4. The soft repair control circuit according to claim 1, wherein
the undo control circuit comprises:
a first latch, wherein an input terminal of the first latch receives the undo enable signal, and a control terminal of the first latch receives the latch control signal; and
a NOT gate, wherein an input terminal of the NOT gate is electrically connected to an output terminal of the first latch, and an output terminal of the NOT gate is configured to output the undo flag signal.

5. The soft repair control circuit according to claim 1, wherein the soft repair address latch circuit comprises at least one sub-latch circuit, and one sub-latch circuit is selected as a target sub-latch circuit according to a preset order, wherein
the target sub-latch circuit is configured to receive the latch control signal and the soft repair fail address, maintain the currently output latched address unchanged when the latch control signal is locked into the first level, and latch the soft repair fail address into the latched address in response to a pulse on the latch control signal when the latch control signal is the inverted delayed signal of the soft repair pulse signal.

6. The soft repair control circuit according to claim 5, wherein the soft repair address matching circuit comprises at least one sub-matching circuit, the at least one sub-matching circuit is connected to the at least one sub-latch circuit in a one-to-one correspondence manner, and one sub-matching circuit correspondingly connected to the target sub-latch circuit serves as a target sub-matching circuit, wherein
the target sub-matching circuit is configured to receive the undo flag signal and the target address, lock the output soft repair matching signal into an inactive level when the undo flag signal is at an active level, and match a corresponding latched address with the target address to generate and output a corresponding soft repair matching signal when the undo flag signal is at an inactive level.

7. The soft repair control circuit according to claim 6, wherein the target sub-latch circuit comprises a plurality of second latches, and the plurality of second latches are in one-to-one correspondence with a plurality of first address signals in the soft repair fail address and a plurality of second address signals in the latched address, wherein
an input terminal of each of the plurality of second latches receives a corresponding one of the plurality of first address signals, a control terminal of the second latch receives the latch control signal, and an output terminal of the second latch is configured to output a corresponding one of the plurality of second address signals.

8. The soft repair control circuit according to claim 7, wherein the target sub-matching circuit comprises a plurality of exclusive NOR gates and an AND gate, and the plurality of exclusive NOR gates are in one-to-one correspondence with the plurality of second latches and a plurality of third address signals in the target address, wherein
a first input terminal of each of the plurality of exclusive NOR gates receives a corresponding one of the plurality of third address signals, and a second input terminal of the exclusive NOR gate is electrically connected to the output terminal of a corresponding one of the plurality of second latches; and
one input terminal of the AND gate receives the undo flag signal, other input terminals of the AND gate are electrically connected to output terminals of the plurality of exclusive NOR gates in a one-to-one correspondence manner, and an output terminal of the AND gate is configured to output the soft repair matching signal.

9. The soft repair control circuit according to claim 1, wherein
the lock control circuit is further configured to reset the latch control signal in response to a reset signal;
the undo control circuit is further configured to reset the undo flag signal to an inactive level in response to the reset signal; and
the soft repair address latch circuit is further configured to reset the latched address in response to the reset signal.

10. A memory, comprising a command decoding circuit and the soft repair control circuit according to any claim 1, wherein
the command decoding circuit is configured to receive a soft repair command, and generate an undo enable signal at an active level when a soft repair mode parameter in the soft repair command is a second preset value; and generate a lock enable signal at an active level when the soft repair mode parameter in the soft repair command is a third preset value; and
the soft repair control circuit is further configured to receive the undo enable signal and the lock enable signal, and control to execute a soft repair undo operation when the undo enable signal is at an active level; and control to execute a soft repair lock operation when the lock enable signal is at an active level.

11. The memory according to claim 10, wherein
the command decoding circuit is further configured to generate a soft repair enable signal at an active level when the soft repair mode parameter in the soft repair command is a first preset value, wherein when the soft repair enable signal is at an active level, it is indicated that the memory enters a soft repair mode;
the command decoding circuit is further configured to, after the memory enters the soft repair mode, sequentially receive an activation command and a write command, decode the activation command to generate and output a soft repair activation signal and a soft repair fail address, and decode the write command to generate and output a soft repair pulse signal, wherein when address information in the activation command indicates a bank corresponding to the soft repair control circuit, the soft repair activation signal at an active level is generated and transmitted to the soft repair control circuit; and
the soft repair control circuit is electrically connected to the command decoding circuit and configured to receive the soft repair activation signal, the soft repair fail address, and the soft repair pulse signal, and latch the soft repair fail address into a latched address according to the soft repair pulse signal when the soft repair activation signal is at an active level.

12. The memory according to claim 11, wherein the memory further comprises: a row address decoding circuit and a bank; and wherein
the command decoding circuit is further configured to generate the soft repair enable signal at an inactive level to indicate that the memory enters a normal operating mode when the soft repair mode parameter in the soft repair command is a fourth preset value;
the command decoding circuit is further configured to receive the activation command and decode the activation command to generate and output the target address when the memory is in the normal operating mode;
the soft repair control circuit is further configured to match the target address with the latched address when the memory is in the normal operating mode, and generate and output a soft repair matching signal at an active level when the target address successfully matches the latched address; and
the row address decoding circuit is electrically connected to the soft repair control circuit and configured to receive the soft repair matching signal and the target address, and control to activate a word line of a corresponding soft repair redundant row in the bank according to the soft repair matching signal at an active level when the soft repair matching signal is at an active level.

13. The memory according to claim 11, wherein the command decoding circuit comprises:
a soft repair command decoder, a mode register, a soft repair signal generation circuit, an activation command decoder, and a write command decoder, wherein
the soft repair command decoder is configured to receive the soft repair command and write the soft repair mode parameter in the soft repair command into the mode register;
the soft repair signal generation circuit is configured to receive the soft repair mode parameter stored in the mode register, and generate the soft repair enable signal at an active level when the soft repair mode parameter is the first preset value; generate the undo enable signal at an active level when the soft repair mode parameter is the second preset value; and
generate the lock enable signal at an active level when the soft repair mode parameter is the third preset value;
the activation command decoder is configured to receive the soft repair enable signal and the activation command, and decode the activation command to generate and output the soft repair activation signal and the soft repair fail address when the soft repair enable signal at an active level indicates that the memory enters the soft repair mode; and
the write command decoder is configured to receive the soft repair enable signal and the write command, and decode the write command to generate and output the soft repair pulse signal when the soft repair enable signal at an active level indicates that the memory enters the soft repair mode.

14. The memory according to claim 12, wherein the memory further comprises:
a fuse address matching circuit, configured to receive a plurality of standard failed addresses from a fuse array, match the received target address with the plurality of standard failed addresses separately, and generate a plurality of standard matching signals according to matching results; and wherein the row address decoding circuit is further configured to receive the plurality of standard matching signals, and control to activate a word line of a corresponding standard redundant row in the bank according to the standard matching signal at an active level when any one of the plurality of standard matching signals is at an active level.

15. The memory according to claim 14, wherein
the row address decoding circuit is further configured to control to activate a word line of a corresponding memory row in the bank according to the target address when both the soft repair matching signal and the standard matching signal are at an inactive level.

16. A method for repairing a memory, comprising:
receiving a soft repair command and decoding the soft repair command;
determining a value of a soft repair mode parameter in the soft repair command;
generating an undo enable signal at an active level to indicate execution of a soft repair undo operation when the soft repair mode parameter is a second preset value;
locking a soft repair matching signal into an inactive level in response to the undo enable signal at an active level;
generating a lock enable signal at an active level to indicate execution of a soft repair lock operation when the soft repair mode parameter is a third preset value; and
maintaining a currently latched soft repair fail address unchanged and shielding the undo enable signal in response to the lock enable signal at an active level, wherein
when the soft repair matching signal is at an inactive level, it is indicated that a target address does not successfully match the latched soft repair fail address, and the target address is an address corresponding to an access operation in a normal operating mode.

17. The repair method according to claim 16, further comprising:
generating a soft repair enable signal at an active level to indicate entry into a soft repair mode when the soft repair mode parameter in the soft repair command is a first preset value;
receiving an activation command and a write command sequentially after the memory enters the soft repair mode;
decoding the activation command to generate a soft repair activation signal and a soft repair fail address;
decoding the write command to generate a soft repair pulse signal; and
latching the soft repair fail address into a latched address according to the soft repair pulse signal in response to the soft repair activation signal at an active level.

18. The repair method according to claim 17, further comprising:
generating the soft repair enable signal at an inactive level to indicate that the memory enters the normal operating mode when the soft repair mode parameter in the soft repair command is a fourth preset value;
receiving the activation command when the memory is in the normal operating mode;
decoding the activation command to generate the target address;
matching the target address with the latched soft repair fail address and generating the soft repair matching signal at an active level when the matching is successful; and
controlling to activate a word line of a corresponding soft repair redundant row in a bank according to the soft repair matching signal at an active level.
